(19) United States
(12) Patent Application Publication
(10) Pub. No.: US 2020/0407383 A1
(43) Pub. Date: Dec. 31, 2020

(54) COMPOUND, ORGANIC ELECTROLUMINESCENCE DEVICE AND DISPLAY DEVICE

(71) Applicant: Shanghai Tianma AM-OLED Co., Ltd., Shanghai (CN)

(72) Inventors: Wenpeng DAI, Shanghai (CN); Wei Gao, Shanghai (CN); Lei Zhang, Shanghai (CN); Jinghua Niu, Shanghai (CN); Ying Liu, Shanghai (CN); Ping An, Shanghai (CN)

(73) Assignee: Shanghai Tianma AM-OLED Co., Ltd., Shanghai (CN)

(21) Appl. No.: 16/591,895

(22) Filed: Oct. 3, 2019

(30) Foreign Application Priority Data
Jun. 28, 2019 (CN) 20190579363.8

(51) Int. Cl. C07F 9/6568; H01L 51/00

(52) U.S. Cl. CPC C07F 9/65685; H01L 51/5072; H01L 51/0071

(57) ABSTRACT

The present disclosure relates to the field of organic electroluminescence, in particular to a compound, an organic electroluminescence device and a display device. The compound has a structure shown in a formula (I):

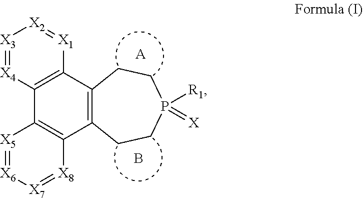

and X is selected from O atom or S atom; X₁-X₈ are each independently selected from C atoms or N atoms, and at least one of X₁-X₈ is N atoms; A and B are each independently selected from any one or more of the substituted or unsubstituted C6-C40 aryl, and substituted or unsubstituted C4-C40 heteroaryl; R₁ is selected from C1-C9 alkyl, substituted or unsubstituted C6-C18 aryl, substituted or unsubstituted C4-C30 heteroaryl.

### CROSS-REFERENCE TO RELATED APPLICATION

This application claims priority of Chinese Patent Application No. 201910579363.8, filed on Jun. 28, 2019, which is hereby incorporated by reference in its entirety.

### FIELD

The present disclosure relates to the field of organic electroluminescence, in particular to a compound, an organic electroluminescence device and a display device.

### BACKGROUND

At present, the widely-used electron transport materials such as batho-phenanthroline (BPhen), bathocuproine (BCP) and TmPyPB generally comply with the market demands of the organic electroluminescent panel.

### SUMMARY

The disclosure provides a compound, an organic electroluminescence device containing the compound and a display device having the organic electroluminescence device.

According to one embodiment of the disclosure, a compound with a structure shown in a formula (I) is provided:

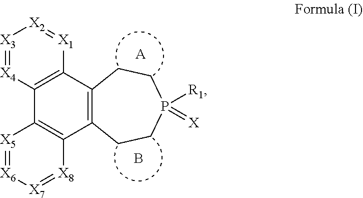

and X is selected from O atom or S atom; X₁-X₈ are each independently selected from C atoms or N atoms, and at least one of X₁-X₈ is N atoms; A and B are each independently selected from any one or more of substituted or unsubstituted C6-C40 aryl, and substituted or unsubstituted C4-C40 heteroaryl;

R₁ is selected from C1-C9 alkyl, substituted or unsubstituted C6-C18 aryl, and substituted or unsubstituted C4-C30 heteroaryl.

According to one embodiment of the disclosure, the C6-C40 aryl is selected from phenyl, naphthyl and anthryl, and the C4-C40 heteroaryl is selected from pyridyl, pyrrolyl, indolyl, pyrimidyl, furyl and thienyl.

According to one embodiment of the disclosure, the C6-C18 aryl is selected from phenyl, naphthyl and anthryl, and the C4-C30 heteroaryl is selected from pyridyl, pyrrolyl, indolyl, pyrimidyl, thienyl, furyl, dibenzothiophenyl, and dibenzofuranyl.

According to one embodiment of the disclosure, two of X₁-X₈ are N atoms.

According to one embodiment of the disclosure,

in X₁-X₈, X₁ and X₃ are N atoms, and the rest are C atoms; or,

in X₁-X₈, X₁ and X₆ are N atoms, and the rest are C atoms; or,

in X₁-X₈, X₁ and X₈ are N atoms, and the rest are C atoms; or,

in X₁-X₈, X₂ and X₃ are N atoms, and the rest are C atoms; or,

in X₁-X₈, X₂ and X₇ are N atoms, and the rest are C atoms; or,

in X₁-X₈, X₃ and X₄ are N atoms, and the rest are C atoms; or,

in X₁-X₈, X₃ and X₅ are N atoms, and the rest are C atoms; or,

in X₁-X₈, X₃ and X₆ are N atoms, and the rest are C atoms; or,

in X₁-X₈, X₄ and X₅ are N atoms, and the rest are C atoms; or,

in X₁-X₈, X₅ and X₆ are N atoms, and the rest are C atoms; or,

in X₁-X₈, X₇ and X₈ are N atoms, and the rest are C atoms.

According to one embodiment of the disclosure,

in X₁-X₈, X₁ and X₈ are N atoms, and the rest are C atoms; or,

in X₁-X₈, X₂ and X₇ are N atoms, and the rest are C atoms; or,

in X₁-X₈, X₃ and X₆ are N atoms, and the rest are C atoms; or,

in X₁-X₈, X₄ and X₅ are N atoms, and the rest are C atoms.

According to one embodiment of the disclosure, among the substituted C6-C40 aryl, substituted C4-C40 heteroaryl, substituted C6-C18 aryl, and substituted C4-C30 heteroaryl, the substituents are each independently selected from any one or more of C1-C10 alkyl or cycloalkyl, C2-C10 alkenyl, C1-C6 alkoxyl, C6-C30 monocyclic aryl or condensed-ring aryl, and C3-C30 monocyclic heteroaryl or condensed-ring heteroaryl.

According to one embodiment of the disclosure, the compound has a structure as shown in a formula (I-1):

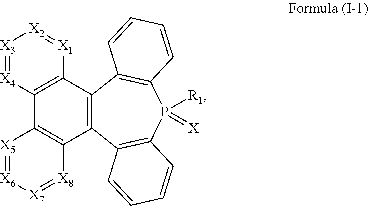

and X is selected from O atom or S atom; X₁-X₈ are each independently selected from C atoms or N atoms, and

R₁ is selected from one or more of

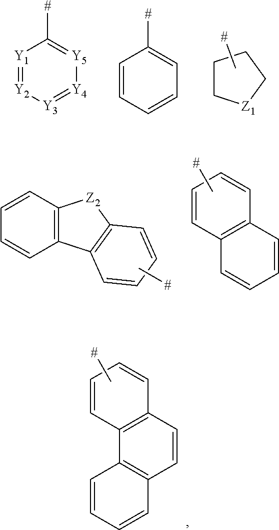

and Y₁-Y₅ are each independently selected from C atoms or N atoms, and Z₁ and Z₂ are each independently selected from O atoms, S atoms or N atoms; and # indicates a connection position.

According to one embodiment of the disclosure, the compound has a structure as shown in a formula (I-2):

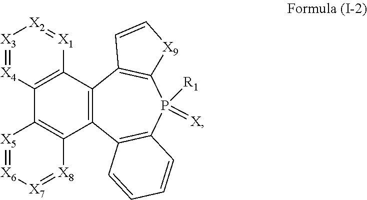

and X is selected from O atom or S atom; X₁-X₈ are each independently selected from C atoms or N atoms, X₉ is selected from O atom, S atom or N atom, and

R₁ is selected from one or more of

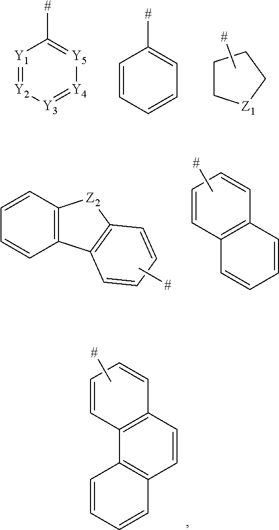

and Y₁-Y₅ are each independently selected from C atoms or N atoms, and Z₁ and Z₂ are each independently selected from O atoms, S atoms or N atoms; and # indicates a connection position.

According to one embodiment of the disclosure, the compound has a structure as shown in a formula (I-3):

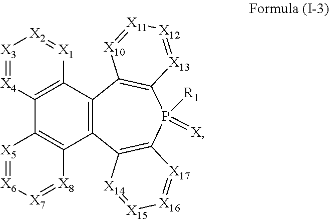

and X is selected from O atom or S atom; X₁-X₈ are each independently selected from C atoms or N atoms, and at least one of X₁₀-X₁₇ is N atoms, and

R₁ is selected from one or more of

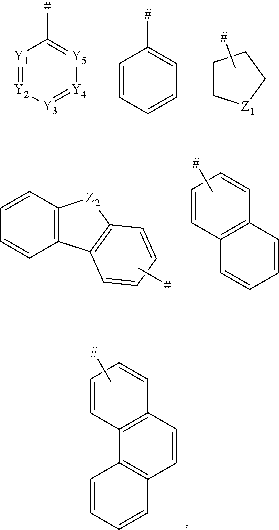

and Y₁-Y₅ are each independently selected from C atoms or N atoms, and Z₁ and Z₂ are each independently selected from O atoms, S atoms or N atoms; and # indicates a connection position.

According to one embodiment of the disclosure, in the formula (I-3), at least one of X₁₀-X₁₃ is N atoms.

According to one embodiment of the disclosure, in the formula (I-3), at least one of X₁₄-X₁₇ is N atoms.

According to one embodiment of the disclosure, the compound has a structure as shown in a formula (I-4):

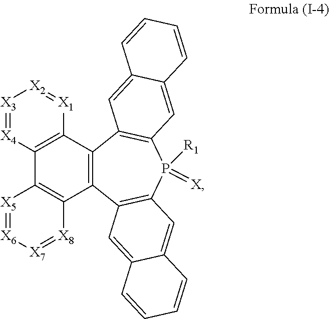

and X is selected from O atom or S atom; X₁-X₈ are each independently selected from C atoms or N atoms, and

R₁ is selected from one or more of

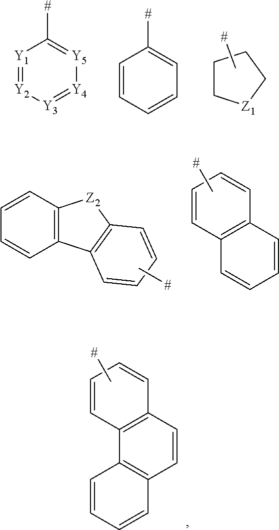

and Y₁-Y₅ are each independently selected from C atoms or N atoms, and Z₁ and Z₂ are each independently selected from O atoms, S atoms or N atoms; and # indicates a connection position.

According to one embodiment of the disclosure, the compound has a structure as shown in a formula (I-5):

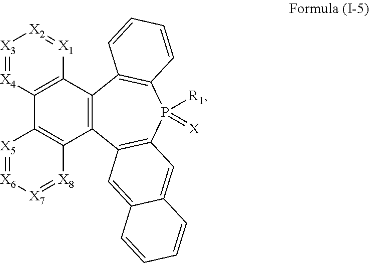

and X is selected from O atom or S atom; X₁-X₈ are each independently selected from C atoms or N atoms, and

R₁ is selected from one or more of

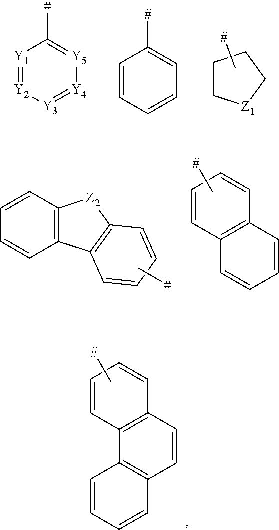

and Y₁-Y₅ are each independently selected from C atoms or N atoms, and Z₁ and Z₂ are each independently selected from O atoms, S atoms or N atoms; and # indicates a connection position.

According to one embodiment of the disclosure, the compound is selected from any one of the following compounds:

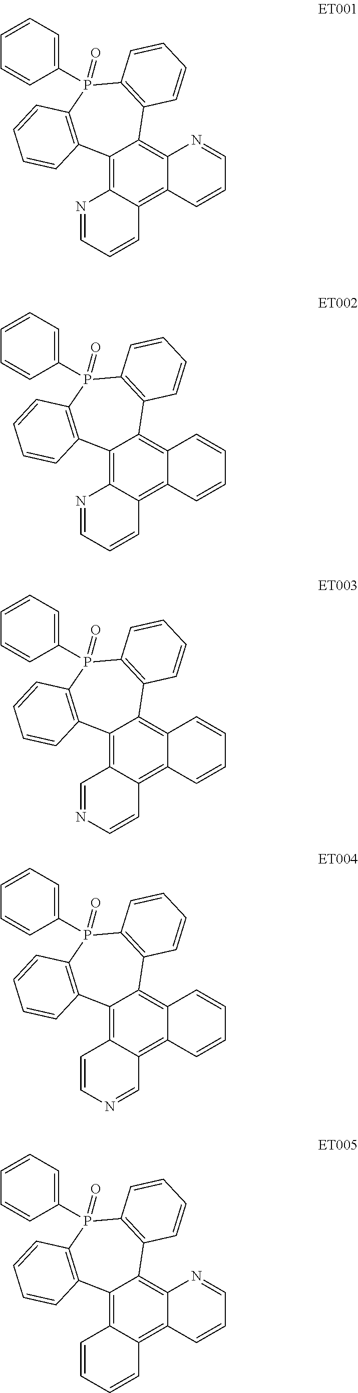 [SMILES: O=P1(c2ccccc2)c2ccccc2-c2c(c3ncccc3c3cccnc23)-c2ccccc21 ; O=P1(c2ccccc2)c2ccccc2-c2c(c3ncccc3c3ccccc23)-c2ccccc21 ; O=P1(c2ccccc2)c2ccccc2-c2c(c3cnccc3c3ccccc23)-c2ccccc21 ; O=P1(c2ccccc2)c2ccccc2-c2c(c3ccncc3c3ccccc23)-c2ccccc21 ; O=P1(c2ccccc2)c2ccccc2-c2c(c3ncccc3c3ccccc23)-c2ccccc21]

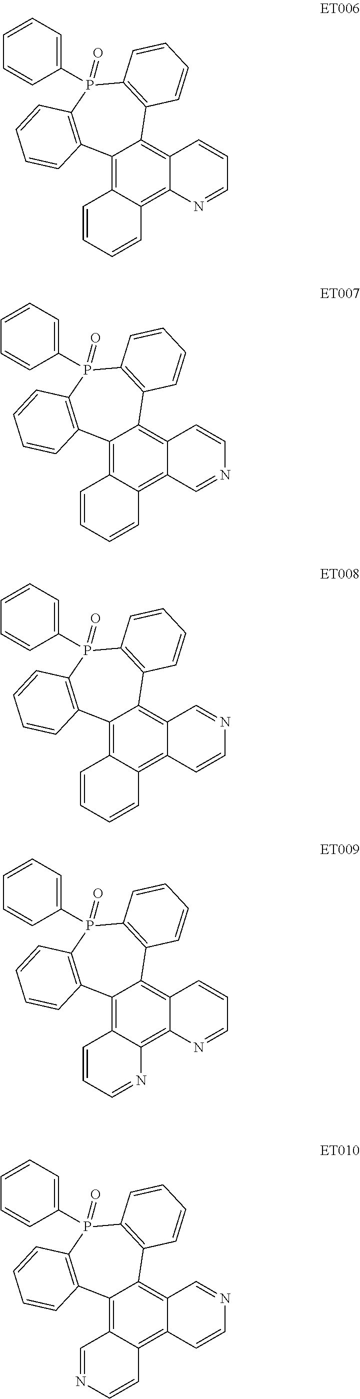 [SMILES: O=P1(c2ccccc2)c2ccccc2-c2c(c3cccnc3c3ccccc23)-c2ccccc21 ; O=P1(c2ccccc2)c2ccccc2-c2c(c3ccncc3c3ccccc23)-c2ccccc21 ; O=P1(c2ccccc2)c2ccccc2-c2c(c3cnccc3c3ccccc23)-c2ccccc21 ; O=P1(c2ccccc2)c2ccccc2-c2c(c3cccnc3c3ncccc23)-c2ccccc21 ; O=P1(c2ccccc2)c2ccccc2-c2c(c3cnccc3c3ccncc23)-c2ccccc21]

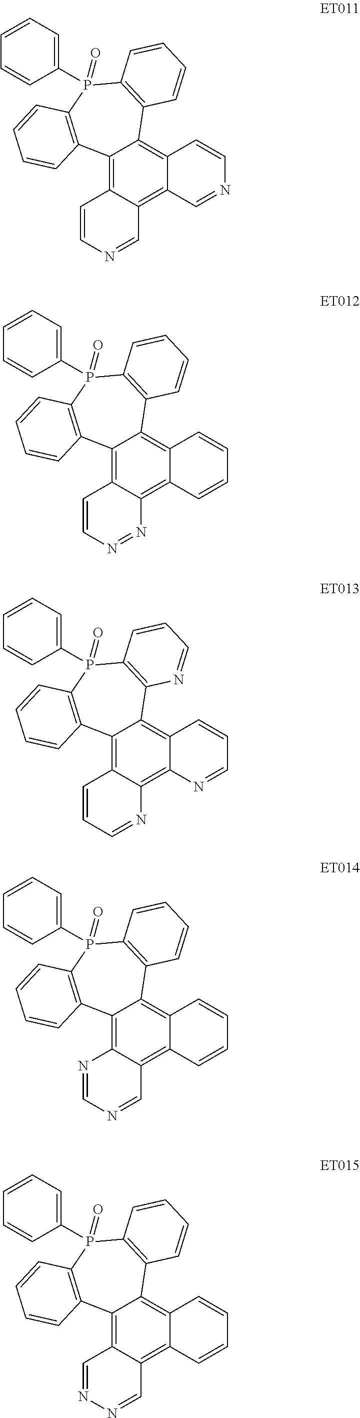 [SMILES: O=P1(c2ccccc2)c2ccccc2-c2c(c3ccncc3c3cnccc23)-c2ccccc21 ; O=P1(c2ccccc2)c2ccccc2-c2c(c3ccnnc3c3ccccc23)-c2ccccc21 ; O=P1(c2ccccc2)c2ccccc2-c2c(c3cccnc3c3ncccc23)-c2ncccc21 ; O=P1(c2ccccc2)c2ccccc2-c2c(c3ncncc3c3ccccc23)-c2ccccc21 ; O=P1(c2ccccc2)c2ccccc2-c2c(c3cnncc3c3ccccc23)-c2ccccc21]

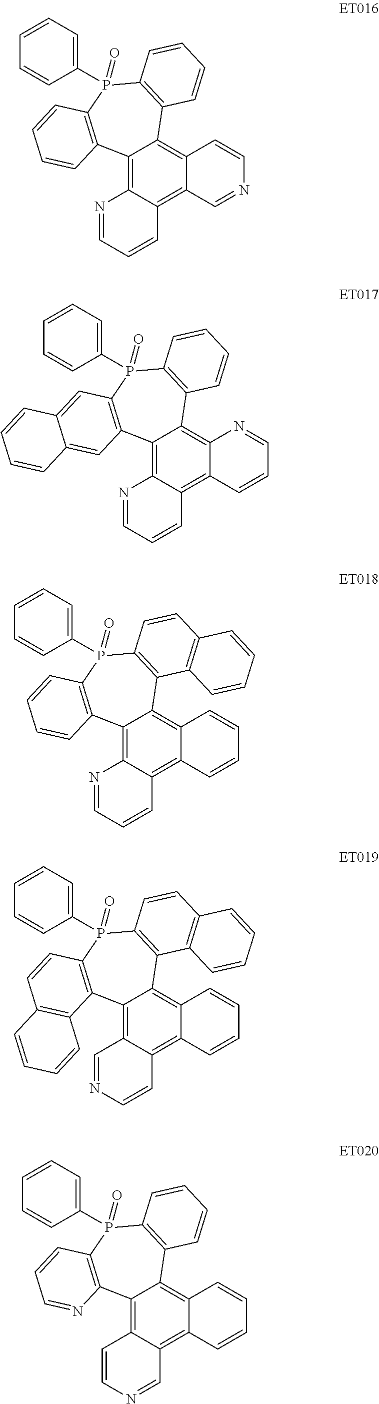 [SMILES: O=P1(c2ccccc2)c2ccccc2-c2c(c3ncccc3c3cnccc23)-c2ccccc21 ; O=P1(c2ccccc2)c2ccccc2-c2c(c3ncccc3c3cccnc23)-c2cc3ccccc3cc21 ; O=P1(c2ccccc2)c2ccccc2-c2c(c3ccccc3c3cccnc23)-c2c1ccc1ccccc21 ; O=P1(c2ccccc2)c2ccc3ccccc3c2-c2c(c3cnccc3c3ccccc23)-c2c1ccc1ccccc21 ; O=P1(c2ccccc2)c2ccccc2-c2c(c3ccncc3c3ccccc23)-c2ncccc21]

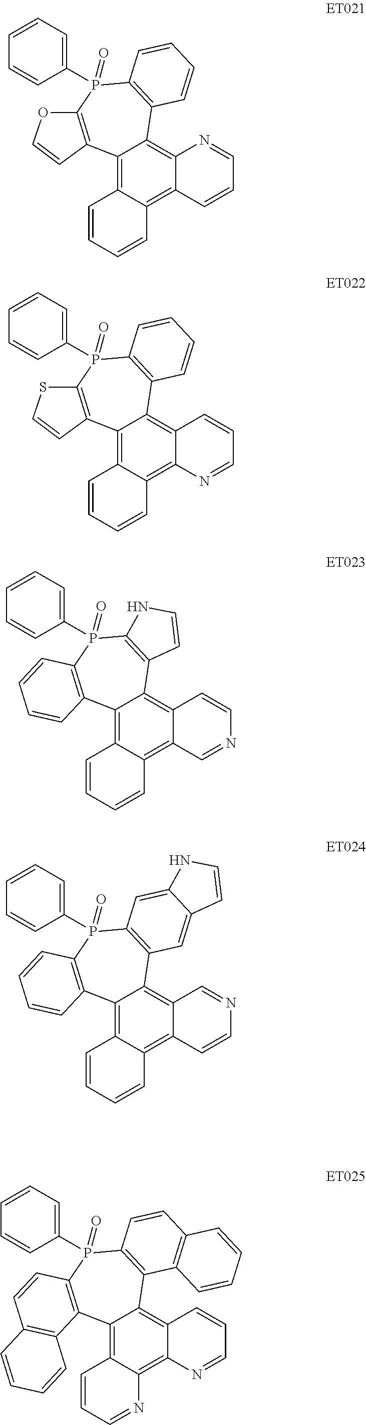 [SMILES: O=P1(c2ccccc2)c2ccccc2-c2c(c3ccccc3c3cccnc23)-c2ccoc21 ; O=P1(c2ccccc2)c2ccccc2-c2c(c3ccccc3c3ncccc23)-c2ccsc21 ; O=P1(c2ccccc2)c2ccccc2-c2c(c3ccncc3c3ccccc23)-c2cc[nH]c21 ; O=P1(c2ccccc2)c2ccccc2-c2c(c3cnccc3c3ccccc23)-c2cc3cc[nH]c3cc21 ; O=P1(c2ccccc2)c2ccc3ccccc3c2-c2c(c3cccnc3c3ncccc23)-c2c1ccc1ccccc21]

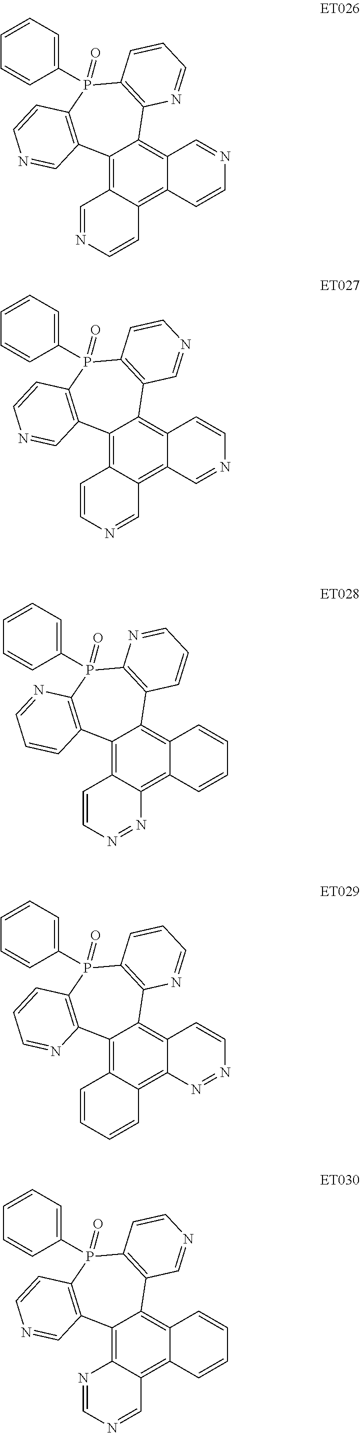 [SMILES: O=P1(c2ccccc2)c2ccncc2-c2c(c3cnccc3c3ccncc23)-c2ncccc21 ; O=P1(c2ccccc2)c2ccncc2-c2c(c3ccncc3c3cnccc23)-c2cnccc21 ; O=P1(c2ccccc2)c2ncccc2-c2c(c3ccnnc3c3ccccc23)-c2cccnc21 ; O=P1(c2ccccc2)c2cccnc2-c2c(c3ccnnc3c3ccccc23)-c2ncccc21 ; O=P1(c2ccccc2)c2ccncc2-c2c(c3ncncc3c3ccccc23)-c2cnccc21]

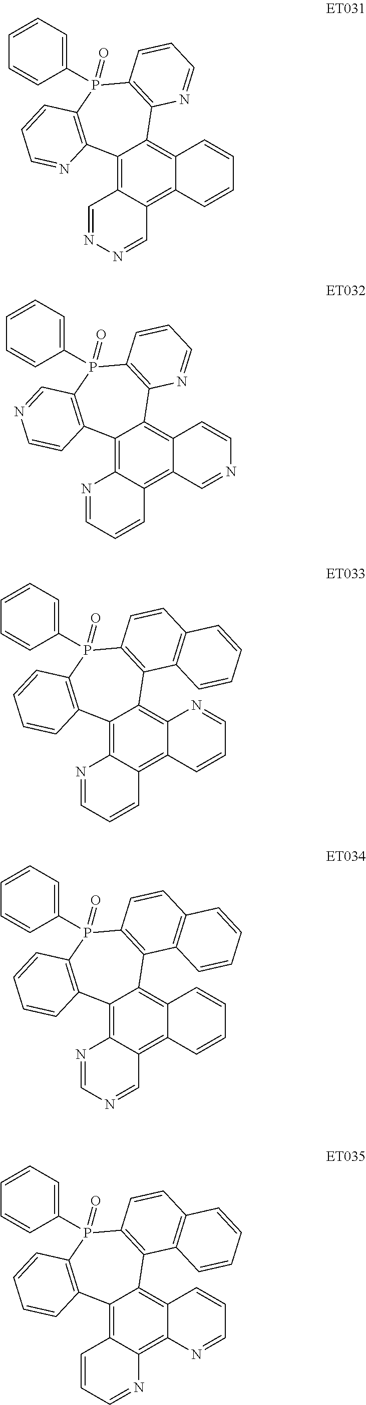 [SMILES: O=P1(c2ccccc2)c2cccnc2-c2c(c3cnncc3c3ccccc23)-c2ncccc21 ; O=P1(c2ccccc2)c2cnccc2-c2c(c3ccncc3c3cccnc23)-c2ncccc21 ; O=P1(c2ccccc2)c2ccccc2-c2c(c3ncccc3c3cccnc23)-c2c1ccc1ccccc21 ; O=P1(c2ccccc2)c2ccccc2-c2c(c3ccccc3c3cncnc23)-c2c1ccc1ccccc21 ; O=P1(c2ccccc2)c2ccccc2-c2c(c3cccnc3c3ncccc23)-c2c1ccc1ccccc21]

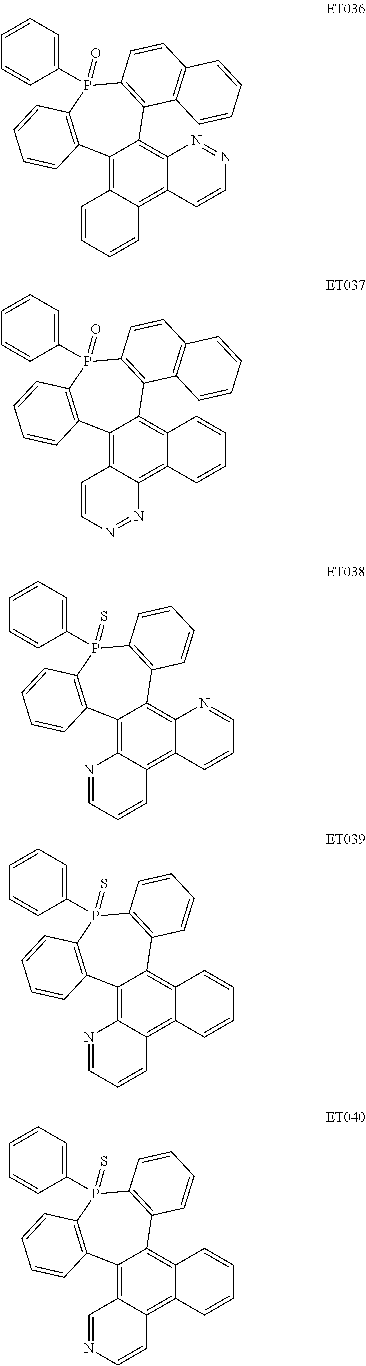 [SMILES: O=P1(c2ccccc2)c2ccccc2-c2c(c3nnccc3c3ccccc23)-c2c1ccc1ccccc21 ; O=P1(c2ccccc2)c2ccccc2-c2c(c3ccccc3c3nnccc23)-c2c1ccc1ccccc21 ; S=P1(c2ccccc2)c2ccccc2-c2c(c3ncccc3c3cccnc23)-c2ccccc21 ; S=P1(c2ccccc2)c2ccccc2-c2c(c3ncccc3c3ccccc23)-c2ccccc21 ; S=P1(c2ccccc2)c2ccccc2-c2c(c3cnccc3c3ccccc23)-c2ccccc21]

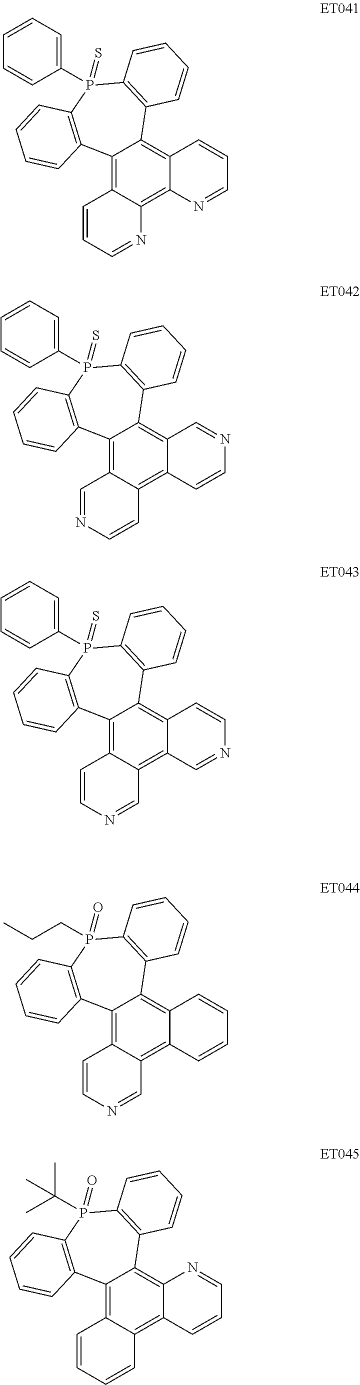 [SMILES: S=P1(c2ccccc2)c2ccccc2-c2c(c3cccnc3c3ncccc23)-c2ccccc21 ; S=P1(c2ccccc2)c2ccccc2-c2c(c3cnccc3c3ccncc23)-c2ccccc21 ; S=P1(c2ccccc2)c2ccccc2-c2c(c3ccncc3c3cnccc23)-c2ccccc21 ; CCCP1(=O)c2ccccc2-c2c(c3ccncc3c3ccccc23)-c2ccccc21 ; CC(C)(C)P1(=O)c2ccccc2-c2c(c3ncccc3c3ccccc23)-c2ccccc21]

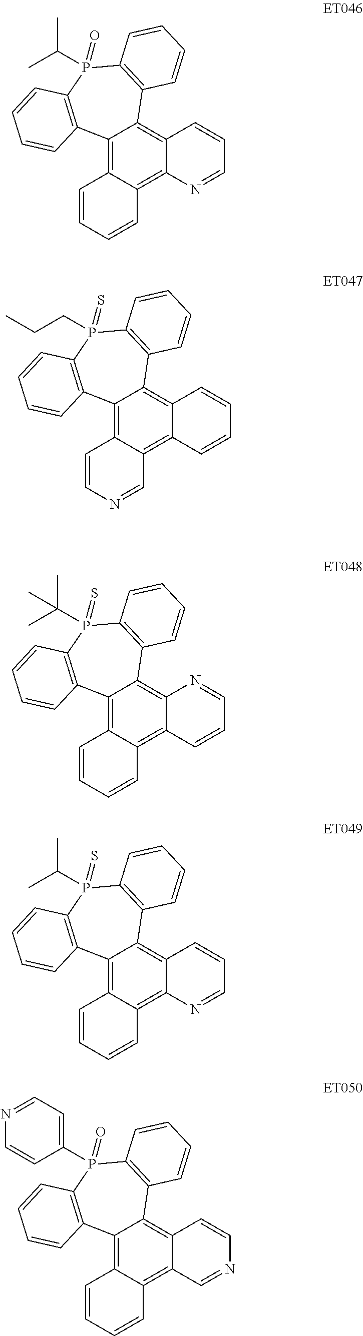 [SMILES: CC(C)P1(=O)c2ccccc2-c2c(c3cccnc3c3ccccc23)-c2ccccc21 ; CCCP1(=S)c2ccccc2-c2c(c3ccncc3c3ccccc23)-c2ccccc21 ; CC(C)(C)P1(=S)c2ccccc2-c2c(c3ncccc3c3ccccc23)-c2ccccc21 ; CC(C)P1(=S)c2ccccc2-c2c(c3cccnc3c3ccccc23)-c2ccccc21 ; O=P1(c2ccncc2)c2ccccc2-c2c(c3ccncc3c3ccccc23)-c2ccccc21]

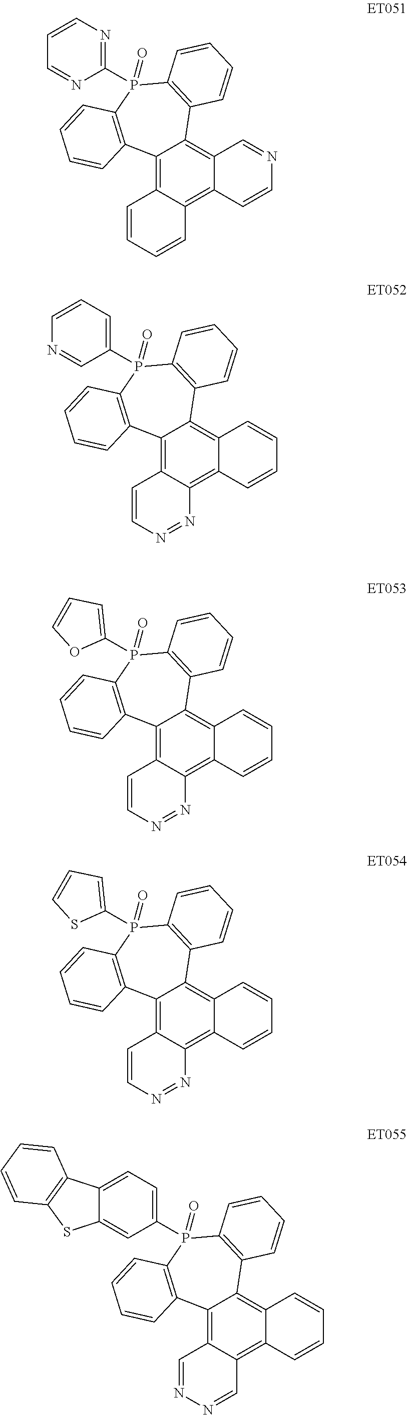 [SMILES: O=P1(c2ncccn2)c2ccccc2-c2c(c3cnccc3c3ccccc23)-c2ccccc21 ; O=P1(c2cccnc2)c2ccccc2-c2c(c3ccnnc3c3ccccc23)-c2ccccc21 ; O=P1(c2ccco2)c2ccccc2-c2c(c3ccnnc3c3ccccc23)-c2ccccc21 ; O=P1(c2cccs2)c2ccccc2-c2c(c3ccnnc3c3ccccc23)-c2ccccc21 ; O=P1(c2ccc3c(c2)sc2ccccc23)c2ccccc2-c2c(c3cnncc3c3ccccc23)-c2ccccc21]

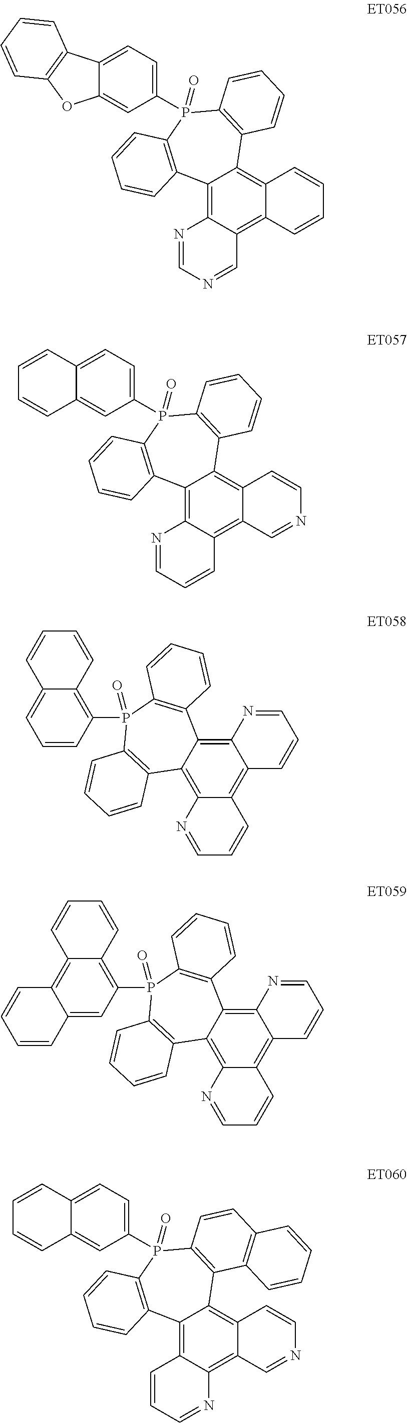 [SMILES: O=P1(c2ccc3c(c2)oc2ccccc23)c2ccccc2-c2c(c3ncncc3c3ccccc23)-c2ccccc21 ; O=P1(c2ccc3ccccc3c2)c2ccccc2-c2c(c3ncccc3c3cnccc23)-c2ccccc21 ; O=P1(c2cccc3ccccc23)c2ccccc2-c2c(c3ncccc3c3cccnc23)-c2ccccc21 ; O=P1(c2cc3ccccc3c3ccccc23)c2ccccc2-c2c(c3ncccc3c3cccnc23)-c2ccccc21 ; O=P1(c2ccc3ccccc3c2)c2ccccc2-c2c(c3ccncc3c3ncccc23)-c2c1ccc1ccccc21]

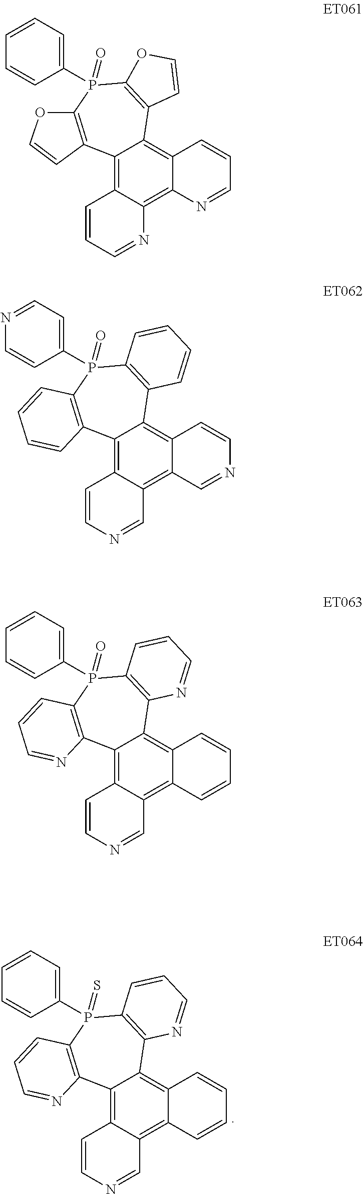 [SMILES: O=P1(c2ccccc2)c2occc2-c2c(c3cccnc3c3ncccc23)-c2ccoc21 ; O=P1(c2ccncc2)c2ccccc2-c2c(c3ccncc3c3cnccc23)-c2ccccc21 ; O=P1(c2ccccc2)c2cccnc2-c2c(c3ccncc3c3ccccc23)-c2ncccc21 ; S=P1(c2ccccc2)c2cccnc2-c2c(c3ccncc3c3ccccc23)-c2ncccc21]

According to one embodiment of the disclosure, the compound is selected from any one of the following compounds:

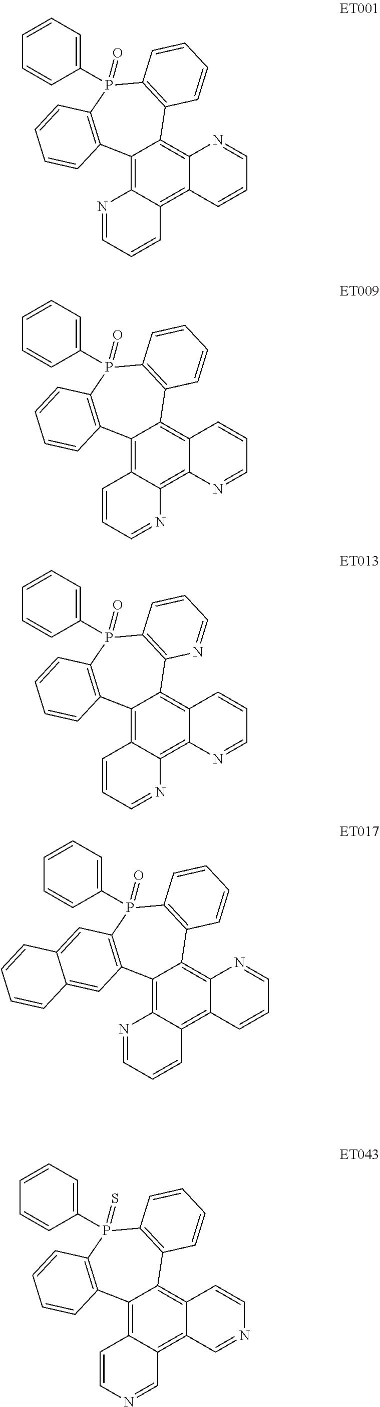 [SMILES: O=P1(c2ccccc2)c2ccccc2-c2c(c3ncccc3c3cccnc23)-c2ccccc21 ; O=P1(c2ccccc2)c2ccccc2-c2c(c3cccnc3c3ncccc23)-c2ccccc21 ; O=P1(c2ccccc2)c2ccccc2-c2c(c3cccnc3c3ncccc23)-c2ncccc21 ; O=P1(c2ccccc2)c2ccccc2-c2c(c3ncccc3c3cccnc23)-c2cc3ccccc3cc21 ; S=P1(c2ccccc2)c2ccccc2-c2c(c3ccncc3c3cnccc23)-c2ccccc21]

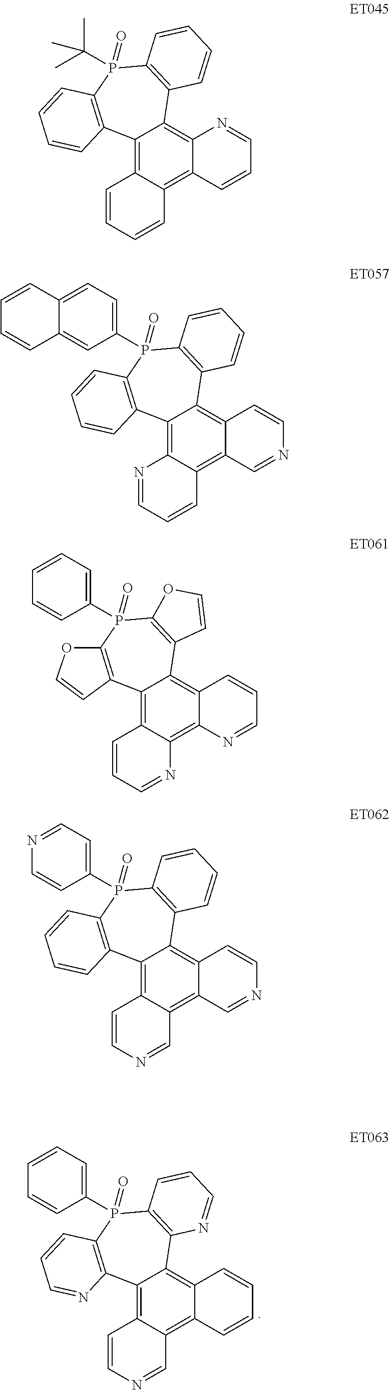 [SMILES: CC(C)(C)P1(=O)c2ccccc2-c2c(c3ncccc3c3ccccc23)-c2ccccc21 ; O=P1(c2ccc3ccccc3c2)c2ccccc2-c2c(c3ncccc3c3cnccc23)-c2ccccc21 ; O=P1(c2ccccc2)c2occc2-c2c(c3cccnc3c3ncccc23)-c2ccoc21 ; O=P1(c2ccncc2)c2ccccc2-c2c(c3ccncc3c3cnccc23)-c2ccccc21 ; O=P1(c2ccccc2)c2cccnc2-c2c(c3ccncc3c3ccccc23)-c2ncccc21]

According to another embodiment of the present disclosure, an organic electroluminescence device is provided, and the organic electroluminescence device includes a first electrode and a second electrode, and an organic function layer between the first electrode and the second electrode, the organic function layer comprises an electron transport layer, and an electron transport material of the electron transport layer includes the compound according to the present disclosure.

According to one embodiment of the disclosure, the organic function layer also includes a hole barrier layer, and an electron transport material of the hole barrier layer includes the compound according to the disclosure.

According to another embodiment of the disclosure, a display device is provided, the display device includes the organic electroluminescence device according to the disclosure.

### BRIEF DESCRIPTION OF THE DRAWINGS

FIG. 1 is a structural diagram of the organic electroluminescence device according to the present disclosure.

FIG. 2 is a schematic diagram of a mobile phone display screen.

### DETAILED DESCRIPTION OF THE EMBODIMENTS

The specific embodiments are only an explanation of the present disclosure, and do not constitute a restriction on the content of the present disclosure. Further explanation and description of the present disclosure will be given in combination with the specific embodiments.

The present disclosure provides an azaphenanthrene compound containing a phosphorus oxygen group, an organic electroluminescence device containing the compound, and a display device having the organic electroluminescence device.

According to one embodiment of the disclosure, a compound with a structure shown in a formula (I) is provided.

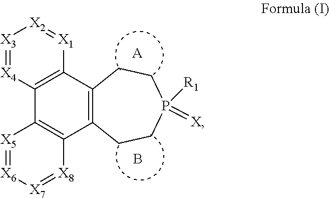

and X is selected from O atom or S atom; X₁ to X₈ are each independently selected from C atoms or N atoms, and at least one of X₁-X₈ is N atoms; A and B are each independently selected from any one or more of substituted or unsubstituted C6-C40 aryl, and substituted or unsubstituted C4-C40 heteroaryl;

R₁ is selected from C1-C9 alkyl, substituted or unsubstituted C6-C18 aryl, and substituted or unsubstituted C4-C30 heteroaryl.

The compound of the present disclosure is azaphenanthrene containing a phosphorus oxygen group, has a suitable HOMO value and a lower LUMO value. When the compound is used as an electron transport material, it can improve electron transport capacity, effectively match with the adjacent layer, effectively block holes from crossing a light-emitting layer, limit the holes within the light-emitting layer, maximumly limit the excitons to glow within the light-emitting layer, has higher triplet energy levels ET, high electron mobility, excellent thermal stability and film stability, and can enhance the luminous efficiency and extend the service life, as well as reduce the driving voltage.

According to one embodiment of the disclosure, the C6-C40 aryl is selected from phenyl, naphthyl and anthryl, and the C4-C40 heteroaryl is selected from pyridyl, pyrrolyl, indolyl, pyrimidyl, furyl and thienyl.

According to one embodiment of the disclosure, the C6-C18 aryl is selected from phenyl, naphthyl and anthryl, and the C4-C30 heteroaryl is selected from pyridyl, pyrrolyl, indolyl, pyrimidyl, thienyl, furyl, dibenzothiophenyl, and dibenzofuranyl.

In the present disclosure, the substituent in the “substituted . . . ” can be selected from any one or more of C1-C10 alkyl or cycloalkyl, C2-C10 alkenyl, C1-C6 alkoxyl, C6-C30 monocyclic aryl or condensed-ring aryl, and C3-C30 monocyclic heteroaryl or condensed-ring heteroaryl.

According to one embodiment of the disclosure, two of X₁-X₈ are N atoms.

According to one embodiment of the disclosure,

in X₁-X₈, X₁ and X₃ are N atoms, and the rest are C atoms; or,

in X₁-X₈, X₁ and X₆ are N atoms, and the rest are C atoms; or,

in X₁-X₈, X₁ and X₈ are N atoms, and the rest are C atoms; or,

in X₁-X₈, X₂ and X₃ are N atoms, and the rest are C atoms; or,

in X₁-X₈, X₂ and X₇ are N atoms, and the rest are C atoms; or,

in X₁-X₈, X₃ and X₄ are N atoms, and the rest are C atoms; or,

in X₁-X₈, X₃ and X₅ are N atoms, and the rest are C atoms; or,

in X₁-X₈, X₃ and X₆ are N atoms, and the rest are C atoms; or,

in X₁-X₈, X₄ and X₅ are N atoms, and the rest are C atoms; or,

in X₁-X₈, X₅ and X₆ are N atoms, and the rest are C atoms; or,

in X₁-X₈, X₇ and X₈ are N atoms, and the rest are C atoms.

According to one embodiment of the disclosure,

in X₁-X₈, X₁ and X₈ are N atoms, and the rest are C atoms; or,

in X₁-X₈, X₂ and X₇ are N atoms, and the rest are C atoms; or,

in X₁-X₈, X₃ and X₆ are N atoms, and the rest are C atoms; or,

in X₁-X₈, X₄ and X₅ are N atoms, and the rest are C atoms.

According to one embodiment of the disclosure, among the substituted C6-C40 aryl, substituted C4-C40 heteroaryl, substituted C6-C18 aryl, and substituted C4-C30 heteroaryl, the substituents are each independently selected from any one or more of C1-C10 alkyl or cycloalkyl, C2-C10 alkenyl, C1-C6 alkoxyl, C6-C30 monocyclic aryl or condensed-ring aryl, and C3-C30 monocyclic heteroaryl or condensed-ring heteroaryl.

According to one embodiment of the disclosure, the compound has a structure as shown in a formula (I-1):

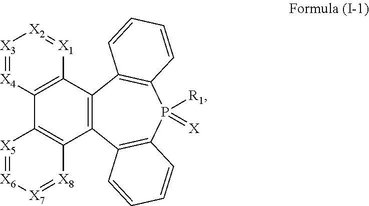

and X is selected from O atom or S atom; X₁-X₈ are independently selected from C atoms or N atoms, and

R₁ is selected from one or more of

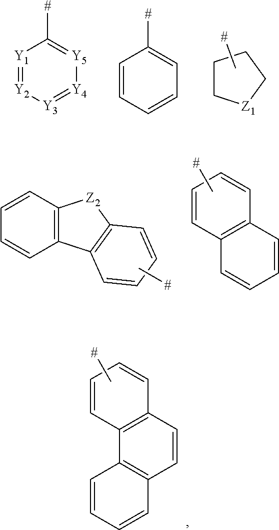

and Y₁-Y₅ are each independently selected from C atoms or N atoms, and Z₁ and Z₂ are each independently selected from O atoms, S atoms or N atoms; and # indicates a connection position.

According to one embodiment of the disclosure, the compound has a structure as shown in a formula (I-2):

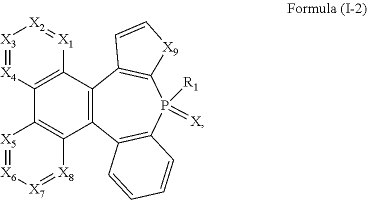

and X is selected from O atom or S atom; X₁-X₈ are each independently selected from C atoms or N atoms, X₉ is selected from O atom, S atom or N atom, and

R₁ is selected from one or more of

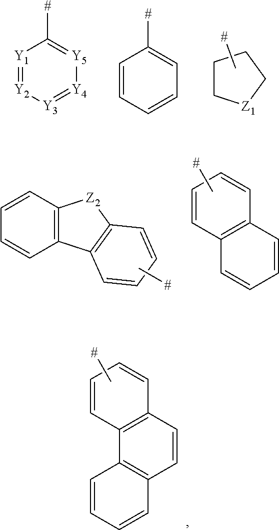

wherein Y₁-Y₅ are each independently selected from C atoms or N atoms, and Z₁ and Z₂ are each independently selected from O atoms, S atoms or N atoms; and # indicates a connection position.

According to one embodiment of the disclosure, the compound has a structure as shown in a formula (I-3):

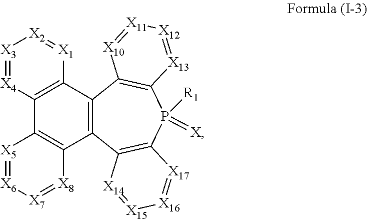

and X is selected from O atom or S atom; X₁-X₈ are each independently selected from C atoms or N atoms, and at least one of X₁₀-X₁₇ is N atoms, and

R₁ is selected from one or more of

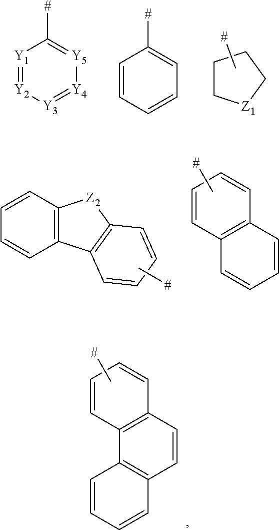

and Y₁-Y₅ are each independently selected from C atoms or N atoms, and Z₁ and Z₂ are each independently selected from O atoms, S atoms or N atoms; and # indicates a connection position.

According to one embodiment of the disclosure, in the formula (I-3), at least one of X₁₀-X₁₃ is N atoms.

According to one embodiment of the disclosure, in the formula (I-3), at least one of X₁₄-X₁₇ is N atoms.

According to one embodiment of the disclosure, the compound has a structure as shown in a formula (I-4):

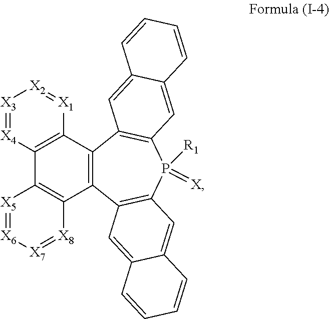

and X is selected from O atom or S atom; X₁-X₈ are each independently selected from C atoms or N atoms, and

R₁ is selected from one or more of

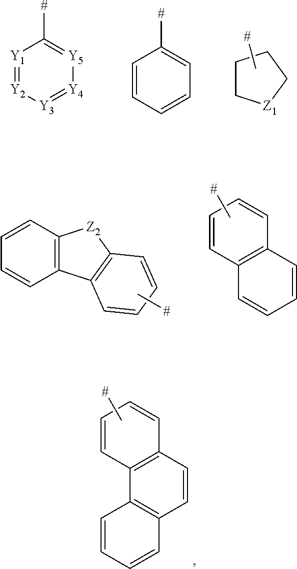

and Y₁-Y₅ are each independently selected from C atoms or N atoms, and Z₁ and Z₂ are each independently selected from O atoms, S atoms or N atoms; and # indicates a connection position.

According to one embodiment of the disclosure, the compound has a structure as shown in a formula (I-5):

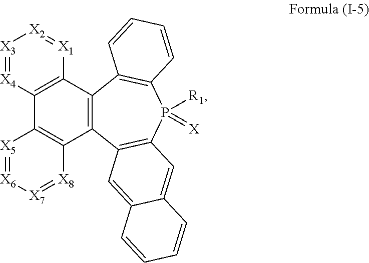

and X is selected from O atom or S atom; X₁-X₈ are each independently selected from C atoms or N atoms, and

R₁ is selected from one or more of

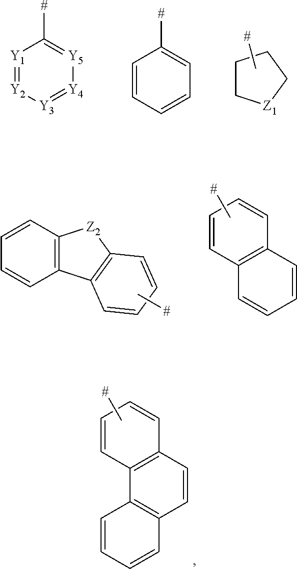

and Y₁-Y₅ are each independently selected from C atoms or N atoms, and Z₁ and Z₂ are each independently selected from O atoms, S atoms or N atoms; and # indicates a connection position.

According to one embodiment of the present disclosure, the compound is selected from any one of ET001 to ET064.

According to one embodiment of the present disclosure, the compound is selected from any one of ET001, ET009, ET013, ET017, ET043, ET045, ET057, ET061, ET062 and ET063.

According to another embodiment of the present disclosure, an organic electroluminescence device is provided, and the organic electroluminescence device includes a first electrode and a second electrode, and an organic function layer between the first electrode and the second electrode, the organic function layer comprises an electron transport layer, and an electron transport material of the electron transport layer includes the compound according to the present disclosure.

According to one embodiment of the disclosure, the organic function layer also includes a hole barrier layer, and an electron transport material of the hole barrier layer includes the compound according to the disclosure.

According to one embodiment of the present disclosure, the organic electroluminescence device comprises a substrate, an anode and a cathode arranged opposite to each other, and an organic function layer between the anode and the cathode. The organic function layer comprises an electron injection layer, electron transport layers, a luminescent layer, hole transport layers and a hole injection layer.

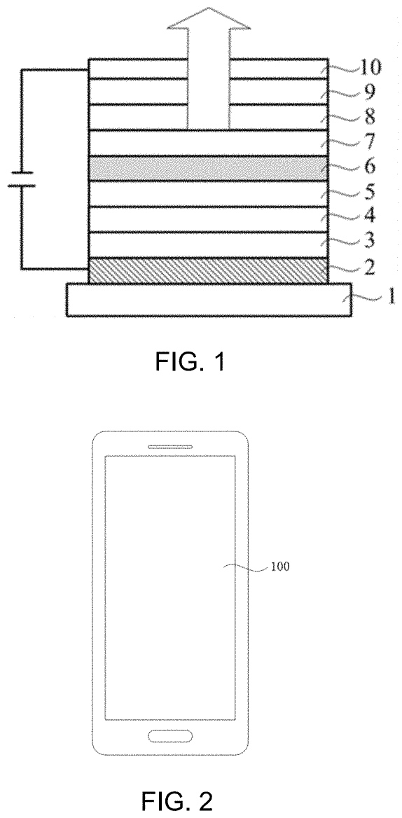

The organic electroluminescence device according to one embodiment of the present disclosure as shown in FIG. 1, includes a substrate 1, an ITO anode 2, a hole injection layer 3, a first hole transport layer 4, a second hole transport layer 5, a luminescent layer 6, a first electron transport layer 7, a second electron transport layer 8, an electron injection layer 9, and a cathode 10 which are arranged in sequence.

The structure of the organic electroluminescence device can be a single luminescent layer or a multi-luminescent layers.

The substrate can use a substrate in a traditional organic electroluminescence device, such as glass or plastic. The anode can be made of transparent and highly conductive materials such as indium tin oxide (ITO), indium zinc oxide (IZO), stannic oxide (SnO₂), and zinc oxide (ZnO).

A hole injection material (HIM) of the hole injection layer requires high thermal stability (high Tg), has a smaller potential barrier with the anode, and can form a pinhole-free film by vacuum evaporation. The commonly-used HIM is aromatic polyamine compounds, mainly triarylamine derivatives.

A hole transport material (HTM) of the hole transport layer requires high thermal stability (high Tg), higher hole transport capacity and the ability to form a pinhole-free film by vacuum evaporation. The commonly-used HTM is aromatic polyamine compounds, mainly triarylamine derivatives.

The organic luminescent layer includes a host material and a guest material, and the guest material is a luminescent material such as dyes, and the host material needs to have the following features: reversible electrochemical redox potential, HOMO and LUMO energy levels matched with the adjacent hole transport layer and electron transport layer, good and matched hole and electron transport capacity, good and high thermal stability and film-forming properties, and appropriate singlet or triplet energy gaps used to control the good energy transfer of excitons between the electroluminescent layer and corresponding fluorescent or phosphorescence dyes. And the luminescent materials of the organic luminescent layer, such as dyes, need to have the following features: the luminescent materials have high fluorescence or phosphorescence quantum efficiency; the absorption spectrum of the dye has a good overlap with the emission spectrum of the host, that is, the host matches the dye in energy to ensure effective energy transfer from the host to the dye; the emission peaks of red, green and blue are as narrow as possible to obtain good color purity; the luminescent materials have good stability and can be used for evaporation.

An electron transport material (ETM) of the electron transport layer requires the ETM to have reversible and sufficiently high electrochemical reduction potential, and appropriate HOMO energy level and LUMO (Lowest Unoccupied Molecular Orbital) energy level value make the injection of electrons better, and it is better to have hole blocking ability, high electron transfer ability, good film-forming properties and thermal stability. ETM is generally an aromatic compound with an electron-deficient conjugate plane. The electron transport layer uses Alq3 (8-hydroxyquinoline aluminum) or TAZ (3-phenyl-4-(1′-naphthyl)-5-phenyl-1,2,4-triazole) or TPBi (1,3,5-tris(N-phenyl-2-benzimidazoly)benzene) or a combination of any two of the three materials.

In the disclosure, a manufacturing process of the organic electroluminescence device is as follows: an anode (the first electrode) is formed on a transparent or opaque smooth substrate, an organic function layer is formed on the anode, and a cathode (the second electrode) is formed on the organic function layer. The formation of the organic function layer can adopt known film-forming methods such as evaporation, sputtering, spin-coating, dipping and ion plating, etc.

According to another embodiment of the present disclosure, a display device is provided, the display device includes the organic electroluminescence device according to the present disclosure.

According to one embodiment of the present disclosure, the display device can be a mobile phone, a computer, a liquid crystal television, a smart watch, a smart car, a VR or AR helmet, etc. The disclosure makes no restrictions on this. FIG. 2 is a schematic diagram of a mobile phone display screen, and 100 represents the display screen.

It can be seen that the optional factors of the compound, the organic electroluminescence device and the display device according to the present disclosure are varied, and different examples can be combined according to the claims of the present disclosure. Examples of the present disclosure are used only as a specific description of the present disclosure and shall not limit the present disclosure. The present disclosure will be further described below with reference to the organic electroluminescence device containing the compound of the present disclosure as an example.

### Synthesis of ET001

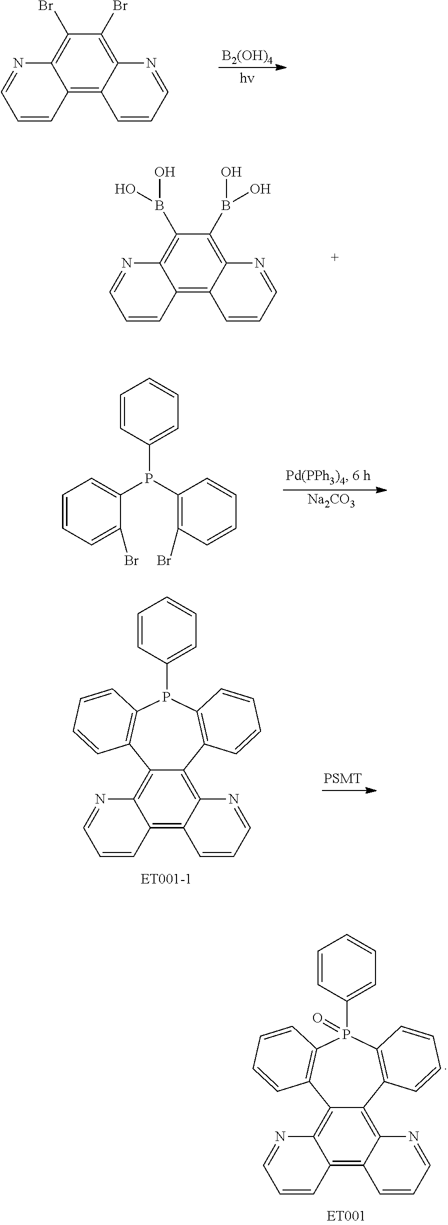

In a 250 ml round-bottom flask, 4,7-dibromo-1,10-phenanthroline (15 mmol) and tetrahydroxydiboron (24 mmol) are added to dried methanol (100 ml), and exposed to UV irradiation (254 nm) under a nitrogen atmosphere to react for 24 hours at a temperature of 15° C., the resulting intermediate mixed solution is added to water, and then is filtered by a diatomite mat, and the resulting filter liquor is extracted by dichloromethane, washed by water, and dried by anhydrous magnesium sulfate, and after filtering and evaporating are performed, a crude product is purified by silica gel column chromatography to obtain an intermediate product 4,7-diborono-1,10-phenanthroline.

In a 250 ml round-bottom flask, 4,7-diborono-1,10-phenanthroline (18 mmol), 10 mol % Pd(PPh₃)₄, Na₂CO₃ (30 mmol) and bis(2-bromophenyl)phenyl phosphine (15 mmol) are added to dried toluene (100 ml), and subjected to reflux under a nitrogen atmosphere for 48 hours, the resulting intermediate is cooled to room temperature and added to water, then filtered by a diatomite mat, and the resulting filter liquor is extracted by dichloromethane, washed by water, and dried by anhydrous magnesium sulfate, and after filtering and evaporating are performed, a crude product is purified by silica gel column chromatography to obtain an intermediate product ET001-1.

In a 250 ml round-bottom flask, ET001-1 (15 mmol) and PSMT (15 mmol) are added to dried methanol (100 ml), and then subjected to a reaction for 24 hours under a nitrogen atmosphere at room temperature, the resulting intermediate mixed solution is added to water, then filtered by a diatomite mat, and the resulting filter liquor is extracted by dichloromethane, washed by water, and dried by anhydrous magnesium sulfate, and after filtering and evaporating are performed, a crude product is purified by silica gel column chromatography to obtain the final product ET001.

The elemental analysis results of the compound ET001 (molecular formula C30H9N2OP): theoretical value: C, 79.12; H, 4.18; N, 6.15; 0, 3.52; P, 6.81. Test value: C, 76.60; H, 4.04; N, 5.96; P, 6.60; S, 6.8. ESI-MS (m/z)(M+) obtained by liquid chromatograph-mass spectrometry analysis: theoretical value: 455.12, and test value: 455.13.

### Synthesis of ET009

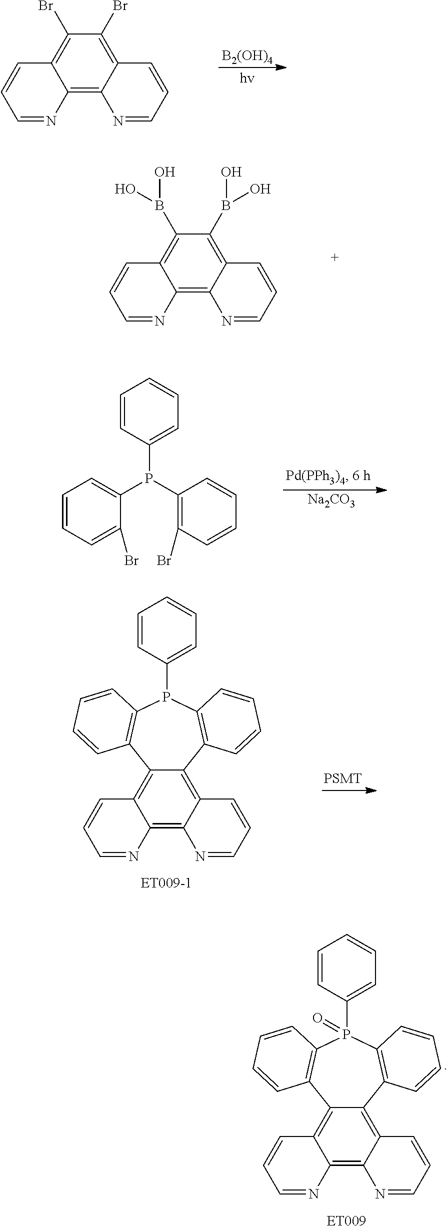

In a 250 ml round-bottom flask, 5,6-dibromo-1,10-phenanthroline (15 mmol) and tetrahydroxydiboron (24 mmol) are added to dried methanol (100 ml), and exposed to UV irradiation (254 nm) under a nitrogen atmosphere to react for 24 hours at a temperature of 15° C., the resulting intermediate mixed solution is added to water, then is filtered by a diatomite mat, and the resulting filter liquor is extracted by dichloromethane, washed by water, and dried by anhydrous magnesium sulfate, and after filtering and evaporating are performed, a crude product is purified by silica gel column chromatography to obtain an intermediate product 5,6-diborono-1,10-phenanthroline.

In a 250 ml round-bottom flask, 5,6-diborono-1,10-phenanthroline (18 mmol), 10 mol % Pd(PPh₃)₄, Na₂CO₃ (30 mmol) and bis(2-bromophenyl)phenyl phosphine (15 mmol) are added to dried toluene (100 ml), and then subjected to reflux under a nitrogen atmosphere for 48 hours, the resulting intermediate is cooled to room temperature and added to water, then filtered by a diatomite mat, and the resulting filter liquor is extracted by dichloromethane, washed by water, and dried by anhydrous magnesium sulfate, and after filtering and evaporating are performed, a crude product is purified by silica gel column chromatography to obtain an intermediate product ET009-1.

In a 250 ml round-bottom flask, ET009-1 (15 mmol) and PSMT (15 mmol) are added to dried methanol (100 ml), and subjected to a reaction for 24 hours under a nitrogen atmosphere at room temperature, the resulting intermediate mixed solution is added to water, then filtered by a diatomite mat, and the resulting filter liquor is extracted by dichloromethane, washed by water, and dried by anhydrous magnesium sulfate, and after filtering and evaporating are performed, a crude product is purified by silica gel column chromatography to obtain the final product ET009.

The elemental analysis results of the compound ET009 (molecular formula C30H19N2OP): theoretical value: C, 79.12; H, 4.18; N, 6.15; 0, 3.52; P, 6.81. Test value: C, 76.60; H, 4.04; N, 5.96; P, 6.60; S, 6.8. ESI-MS (m/z)(M+) obtained by liquid chromatograph-mass spectrometry analysis: theoretical value: 455.12, and test value: 455.13.

### Synthesis of ET013

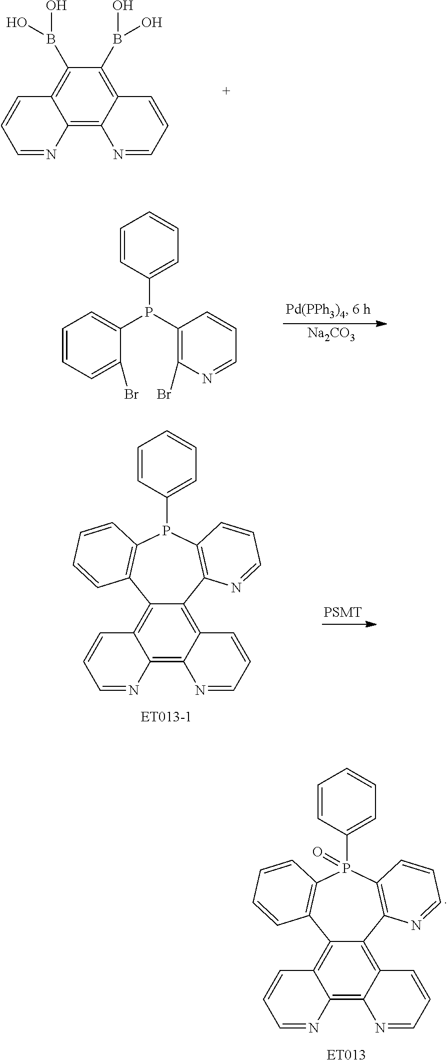

In a 250 ml round-bottom flask, 5,6-diborono-1,10-phenanthroline (18 mmol), 10 mol % Pd(PPh₃)₄, Na₂CO₃ (30 mmol) and 2-bromo-3-[(2-bromo-phenyl)-phenyl phosphoryl]-pyridine (15 mmol) are added to dried toluene (100 ml), and subjected to reflux under a nitrogen atmosphere for 48 hours, the resulting intermediate is cooled to room temperature and added to water, then filtered by a diatomite mat, and the resulting filter liquor is extracted by dichloromethane, washed by water, and dried by anhydrous magnesium sulfate, and after filtering and evaporating are performed, a crude product is purified by silica gel column chromatography to obtain an intermediate product ET013-1.

In a 250 ml round-bottom flask, ET013-1 (15 mmol) and PSMT (15 mmol) are added to the dried methanol (100 ml), and subjected to a reaction for 24 hours under a nitrogen atmosphere at room temperature, the resulting intermediate mixed solution is added to water, then filtered by a diatomite mat, and the resulting filter liquor is extracted by dichloromethane, washed by water, and dried by anhydrous magnesium sulfate, and after filtering and evaporating are performed, a crude product is purified by silica gel column chromatography to obtain the final product ET013.

The elemental analysis results of the compound ET013 (molecular formula C29H18N3OP): theoretical value: C, 76.65; H, 3.95; N, 9.25; 0, 3.52; P, 6.83. Test value: C, 76.65; H, 3.95; N, 9.25; 0, 3.52; P, 6.83. ESI-MS (m/z)(M+) obtained by liquid chromatograph-mass spectrometry analysis: theoretical value: 454.12, and test value: 454.13.

### Synthesis of ET017

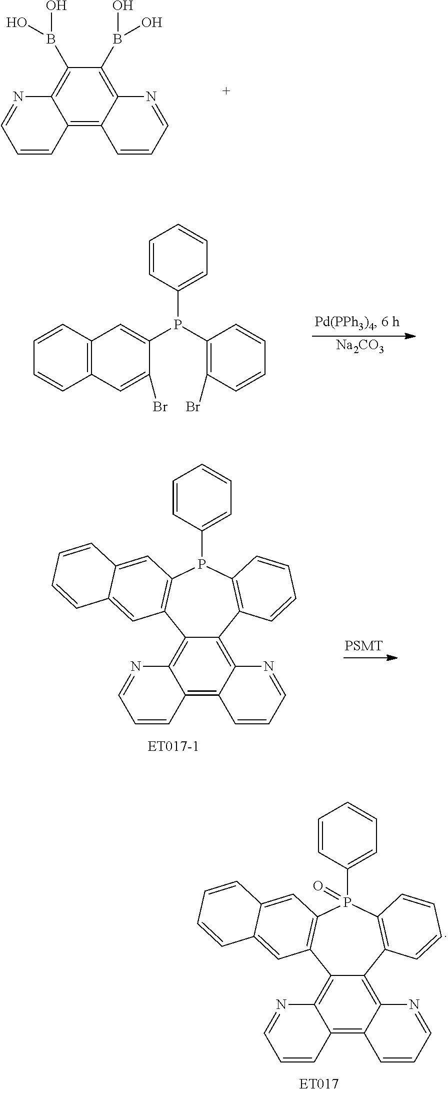

In a 250 ml round-bottom flask, 4,7-diborono-1,10-phenanthroline (18 mmol), 10 mol % Pd(PPh₃)₄, Na₂CO₃ (30 mmol) and (3-bromo-naphthalen-2-yl)-(2-bromo-phenyl)-phenylphosphine (15 mmol) are added to dried toluene (100 ml), and subjected to reflux under a nitrogen atmosphere for 48 hours, the resulting intermediate is cooled to room temperature and added to water, then filtered by a diatomite mat, and the resulting filter liquor is extracted by dichloromethane, washed by water, and dried by anhydrous magnesium sulfate, and after filtering and evaporating are performed, a crude product is purified by silica gel column chromatography to obtain an intermediate product ET017-1.

In a 250 ml round-bottom flask, ET017-1 (15 mmol) and PSMT (15 mmol) are added to dried methanol (100 ml), and subjected to a reaction for 24 hours under a nitrogen atmosphere at room temperature, the resulting intermediate mixed solution is added to water, then filtered by a diatomite mat, and the resulting filter liquor is extracted by dichloromethane, washed by water, and dried by anhydrous magnesium sulfate, and after filtering and evaporating are performed, a crude product is purified by silica gel column chromatography to obtain the final product ET017.

The elemental analysis results of the compound ET017 (molecular formula C34H21N2OP): theoretical value: C, 80.95; H, 4.17; N, 5.56; 0, 3.17; P, 6.15. Test value: C, 80.95; H, 4.17; N, 5.56; 0, 3.17; P, 6.15. ESI-MS (m/z)(M+) obtained by liquid chromatograph-mass spectrometry analysis: theoretical value: 504.14, and test value: 504.13.

### Synthesis of ET043

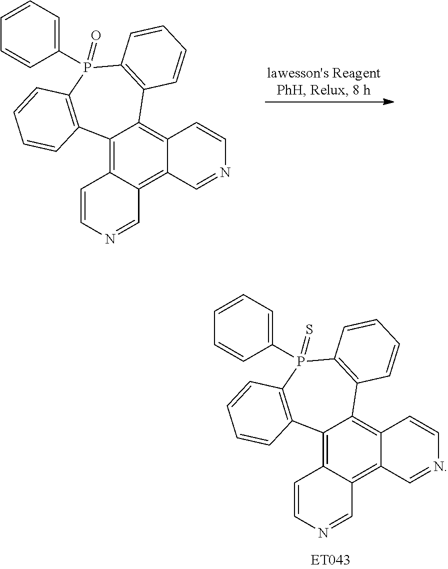 [SMILES: O=P1(c2ccccc2)c2ccccc2-c2c(c3ccncc3c3cnccc23)-c2ccccc21 ; S=P1(c2ccccc2)c2ccccc2-c2c(c3ccncc3c3cnccc23)-c2ccccc21]

In a 250 ml round-bottom flask, ET001(15 mmol) and a Lawesson's Reagent (30 mmol) are added to dried benzene (100 ml), and subjected to reflux under a nitrogen atmosphere for 8 hours, the resulting intermediate is cooled to room temperature and added to water, then filtered by a diatomite mat, and the resulting filter liquor is extracted by dichloromethane, washed by water, and dried by anhydrous magnesium sulfate, and after filtering and evaporating, a crude product is purified by silica gel column chromatography to obtain an intermediate product ET043.

The elemental analysis results of the compound ET043 (molecular formula C30H9N2PS): theoretical value: C, 76.60; H, 4.04; N, 5.96; P, 6.60; S, 6.8. Test value: C, 76.60; H, 4.04; N, 5.96; P, 6.60; S, 6.8. ESI-MS (m/z)(M+) obtained by liquid chromatograph-mass spectrometry analysis: theoretical value: 470.10, and test value: 470.09.

### Synthesis of ET057

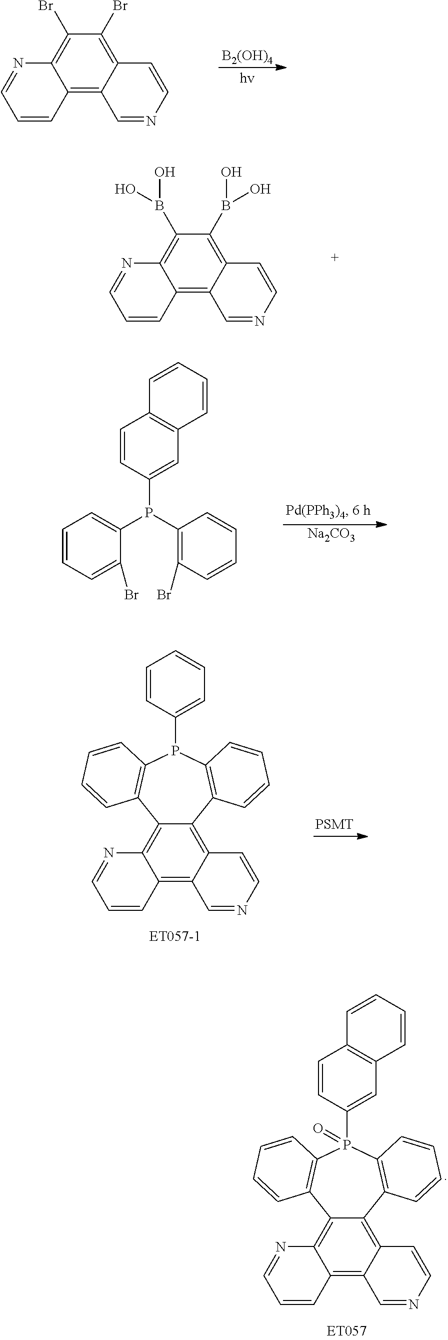

In a 250 ml round-bottom flask, 4,6-diborono-1,10-phenanthroline (18 mmol), 10 mol % Pd(PPh₃)₄, Na₂CO₃ (30 mmol) and bis(2-bromo-phenyl)-naphthalen-2-yl-phosphine (15 mmol) are added to dried toluene (100 ml), and subjected to reflux under a nitrogen atmosphere for 48 hours, the resulting intermediate is cooled to room temperature and added to water, then filtered by a diatomite mat, and the resulting filter liquor is extracted by dichloromethane, washed by water, and dried by anhydrous magnesium sulfate, and after filtering and evaporating are performed, a crude product is purified by silica gel column chromatography to obtain an intermediate product ET057-1.

In a 250 ml round-bottom flask, ET057-1 (15 mmol) and PSMT (15 mmol) are added to dried methanol (100 ml), and subjected to a reaction for 24 hours under nitrogen atmosphere at room temperature, the resulting intermediate mixed solution is added to water, then filtered by a diatomite mat, and the resulting filter liquor is extracted by dichloromethane, washed by water, and dried by anhydrous magnesium sulfate, and after filtering and evaporating are performed, a crude product is purified by silica gel column chromatography to obtain the final product ET057.

The elemental analysis results of the compound ET057 (molecular formula C34H21N2OP): theoretical value: C, 80.95; H, 4.17; N, 5.56; O, 3.17; P, 6.15. Test value: C, 80.95; H, 4.17; N, 5.56; O, 3.17; P, 6.15. ESI-MS (m/z)(M+) obtained by liquid chromatograph-mass spectrometry analysis: theoretical value: 504.14, and test value: 504.13.

Other compounds are obtained by adopting similar synthetic methods.

Performance Test.

(1) Compound Simulation Calculation.

The singlet and triplet energy level difference of organic materials can be completed by the software Guassian 09 (Guassian Inc.). Please refer to J. Chem. Theory Comput., 2013, DOI:10.1021/ct400415r for the specific simulation method of energy level difference ΔEst. The optimization and excitation of a molecular structure can all be done by a TD-DFT method “B3LYP” and a basis set “6-31 g (d)”, and Tg is measured by differential scanning calorimetry. In this application, compounds ET001, ET009, E013, ET017, ET043, ET045, ET057, ET061, ET062 and ET063 are subjected to simulated calculation, and the results are shown in Table 1.

TABLE 1

| Serial No. | Compound | HOMO(eV) | LUMO(eV) | E_{T} (eV) |
|---|---|---|---|---|
| Example 1 | ET001 | −5.920 | −1.604 | 2.6513 |
| Example 2 | ET009 | −5.907 | −1.507 | 2.6535 |
| Example 3 | ET013 | −5.902 | −1.931 | 2.7043 |
| Example 4 | ET017 | −5.790 | −1.654 | 2.5403 |
| Example 5 | ET043 | −5.120 | −1.972 | 2.6235 |
| Example 6 | ET045 | −5.690 | −1.951 | 2.6603 |
| Example 7 | ET057 | −5.893 | −1.990 | 2.5623 |
| Example 8 | ET061 | −6.007 | −1.999 | 2.6383 |
| Example 9 | ET062 | −5.946 | −2.142 | 2.7143 |
| Example 10 | ET063 | −5.917 | −2.014 | 2.7658 |

As can be seen from Table 1, the compounds prepared by examples of the present disclosure can be used as electron transport materials, have appropriate HOMO values and lower LUMO values, can improve electron transport ability and effectively block holes. At the same time, the compounds have higher triplet energy levels ET, high electron mobility, excellent thermal stability and film stability, which facilitates the improvement of luminous efficiency.

### Application Examples 1-10 and Comparison Examples 1-2

The compounds and structure thereof involved in the application examples are shown below:

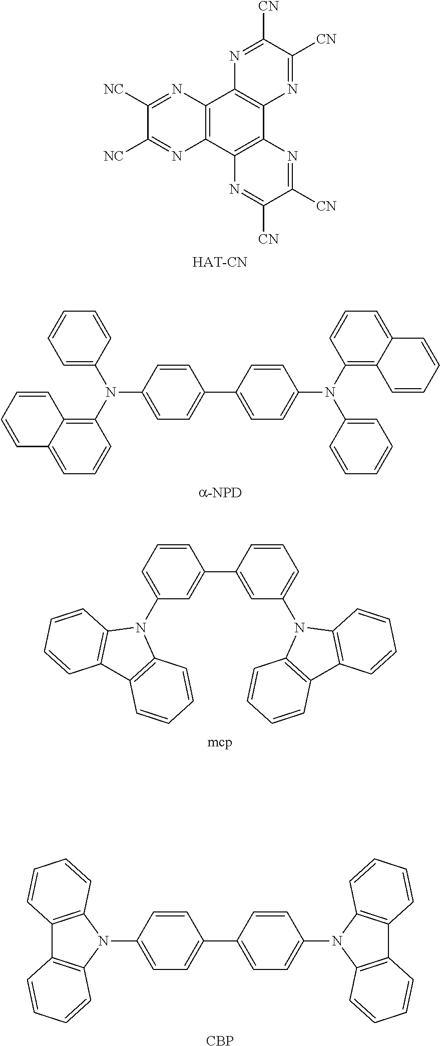 [SMILES: N#Cc1nc2c3nc(C#N)c(C#N)nc3c3nc(C#N)c(C#N)nc3c2nc1C#N ; c1ccc(N(c2ccc(-c3ccc(N(c4ccccc4)c4cccc5ccccc45)cc3)cc2)c2cccc3ccccc23)cc1 ; c1cc(-c2cccc(-n3c4ccccc4c4ccccc43)c2)cc(-n2c3ccccc3c3ccccc32)c1 ; c1ccc2c(c1)c1ccccc1n2-c1ccc(-c2ccc(-n3c4ccccc4c4ccccc43)cc2)cc1 ; "CBP"]

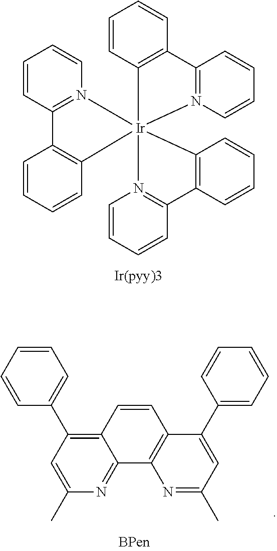

The example provides an OLED device, as shown in FIG. 1. The OLED device includes: a substrate 1, an ITO anode 2, a hole injection layer 3, a first hole transport layer 4, a second hole transport layer 5, a luminescent layer 6, a first electron transport layer 7, a second electron transport layer 8, an electron injection layer 9, and a cathode 10 (an aluminum electrode), and the thickness of the ITO anode 2 is 10 nm, the thickness of the hole injection layer 3 is 5 nm, the thickness of the first hole transport layer 4 is 50 nm, the thickness of the second hole transport layer 5 is 10 nm, the thickness of the luminescent layer 6 is 20 nm, the thickness of the first electron transport layer 7 is 5 nm, the thickness of the second electron transport layer 8 is 20 nm, the thickness of the electron injection layer 9 is 1 nm, and the thickness of the aluminum electrode 10 is 15 nm.

The preparation steps of the OLED device of the present disclosure are as follows:

1) The glass substrate 1 is cut into a size of 50 mm×50 mm×0.7 mm, is treated by ultrasonic in isopropyl alcohol and deionized water for 30 minutes respectively, and then exposed to ozone for about 10 minutes for cleaning; the resulting glass substrate 1 with the ITO anode 2 is installed on the vacuum deposition equipment;

2) A hole injection layer material HAT-CN is evaporated by vacuum evaporation on an ITO anode layer 2 under a vacuum degree of 2×10−6 Pa, and the thickness is 5 nm, and this layer is used as the hole injection layer 3.

3) A material, namely N,N′-diphenyl-N,N′-(1-naphthalenyl)-1,1′-biphenyl-4,4′-diamine (α-NPD) of the first hole transport layer 4 is evaporated by vacuum evaporation on the hole injection layer 3, and the thickness is 50 nm, and this layer is used as the first hole transport layer 4.

4) A material, namely 1,3-dicarbazol-9-ylbenzene (mCP) of the second hole transport layer 5 is evaporated by vacuum evaporation on the first hole transport layer 4, and the thickness is 10 nm, and this layer is used as the second hole transport layer 5.

5) The luminescent layer 6 is co-deposited on the second hole transport layer 5, and the host material of the luminescent layer 6 is CBP, the guest material is Ir(pyy)3, the mass ratio of the compound CBP to Ir(ppy)3 is 97:3, and the thickness is 20 nm.

6) The first electron transport layer 7 is evaporated by vacuum evaporation on the luminescent layer 6, and a material of the first electron transport layer 7 is the compounds of the present disclosure or the compounds of Comparison examples 1 and 2, with a thickness of 5 nm;

7) The second electron transport layer 8 is evaporated by vacuum evaporation on the first electron transport layer 7, and a material of the second electron transport layer 8 is BPen with a thickness of 20 nm;

8) The electron injection layer 9 is evaporated by vacuum evaporation on the second electron transport layer 8, and a material of the electron injection layer 9 is LiF and the thickness is 1 nm; and

9) The aluminum electrode is evaporated by vacuum evaporation on the electron injection layer 9, and the aluminum electrode is 15 nm thick and used as the cathode 10.

The performance of the organic electroluminescence device is shown in Table 2.

TABLE 2

| | Electron | Driving | Current | | Service |
|---|---|---|---|---|---|
| | Transport | Voltage | Efficiency | EQE(max) | Life |
| | Material | V | cd/A | (%) | LT95 |
| Comparison | Alq3 | 4.22 | 62.7 | 6.9 | 111.2 |
| Example 1 | | | | | |
| Comparison | BPhen | 4.28 | 65.7 | 6.6 | 123.4 |
| Example 2 | | | | | |
| Example 1 | ET001 | 3.78 | 76.5 | 6.4 | 131.2 |
| Example 2 | ET009 | 3.82 | 74.8 | 14.3 | 130.2 |
| Example 3 | ET013 | 3.95 | 75.6 | 7.0 | 131.1 |
| Example 4 | ET017 | 3.70 | 76.9 | 7.8 | 130.4 |
| Example 5 | ET043 | 3.91 | 83.6 | 8.2 | 129.5 |
| Example 6 | ET045 | 3.78 | 78.5 | 12.3 | 130.8 |
| Example 7 | ET057 | 3.91 | 79.6 | 9.7 | 132.0 |
| Example 8 | ET061 | 3.74 | 77.1 | 12.4 | 131.4 |
| Example 9 | ET062 | 3.80 | 82.9 | 6.7 | 130.5 |
| Example 10 | ET063 | 3.90 | 78.6 | 8.9 | 130.9 |

As can be seen from Table 2, the OLED device provided by the present disclosure has lower driving voltage, higher luminous efficiency and service life. Compared with the Comparison Examples, the examples of the disclosure have the advantages that the driving voltage is less than 3.95V, increasing by 7.0%; the luminous efficiency is greater than 75 Cd/A, increasing by 13.3%; and the service life is greater than 130 h, increasing by 5.4%. Compared with the Comparison Examples, the above performance of the display panel is significantly improved, which is mainly due to the material of the disclosure having a deeper HOMO value and a higher triplet energy level, which can effectively prevent the backflowing of excitons and holes from crossing the luminescent layer.

What is claimed is:

1. A compound, wherein the compound has a structure as shown in a formula (I): 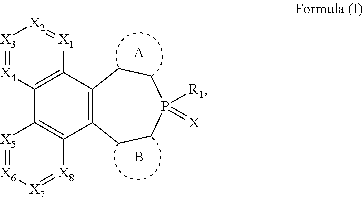
wherein X is selected from O atom or S atom; X₁-X₈ are each independently selected from C atoms or N atoms, and at least one of X₁-X₈ is N atoms; A and B are each independently selected from any one or more of substituted or unsubstituted C6-C40 aryl, and substituted or unsubstituted C4-C40 heteroaryl; and
R₁ is selected from C1-C9 alkyl, substituted or unsubstituted C6-C18 aryl, and substituted or unsubstituted C4-C30 heteroaryl.

2. The compound according to claim 1, wherein the C6-C40 aryl is selected from phenyl, naphthyl and anthryl, and the C4-C40 heteroaryl is selected from pyridyl, pyrrolyl, indolyl, pyrimidyl, furyl and thienyl.

3. The compound according to claim 1, wherein the C6-C18 aryl is selected from phenyl, naphthyl and anthryl, and the C4-C30 heteroaryl is selected from pyridyl, pyrrolyl, indolyl, pyrimidyl, thienyl, furyl, dibenzothiophenyl, and dibenzofuranyl.

4. The compound according to claim 1, wherein two of X₁-X₈ are N atoms.

5. The compound according to claim 1, wherein
in X₁-X₈, X₁ and X₃ are N atoms, and the rest are C atoms; or,
in X₁-X₈, X₁ and X₆ are N atoms, and the rest are C atoms; or,
in X₁-X₈, X₁ and X₈ are N atoms, and the rest are C atoms; or,
in X₁-X₈, X₂ and X₃ are N atoms, and the rest are C atoms; or,
in X₁-X₈, X₂ and X₇ are N atoms, and the rest are C atoms; or,
in X₁-X₈, X₃ and X₄ are N atoms, and the rest are C atoms; or,
in X₁-X₈, X₃ and X₅ are N atoms, and the rest are C atoms; or,
in X₁-X₈, X₃ and X₆ are N atoms, and the rest are C atoms; or,
in X₁-X₈, X₄ and X₅ are N atoms, and the rest are C atoms; or,
in X₁-X₈, X₅ and X₆ are N atoms, and the rest are C atoms; or,
in X₁-X₈, X₇ and X₈ are N atoms, and the rest are C atoms.

6. The compound according to claim 1, wherein
in X₁-X₈, X₁ and X₈ are N atoms, and the rest are C atoms; or,
in X₁-X₈, X₂ and X₇ are N atoms, and the rest are C atoms; or,
in X₁-X₈, X₃ and X₆ are N atoms, and the rest are C atoms; or,
in X₁-X₈, X₄ and X₅ are N atoms, and the rest are C atoms.

7. The compound according to claim 1, wherein among the substituted C6-C40 aryl, substituted C4-C40 heteroaryl, substituted C6-C18 aryl, and substituted C4-C30 heteroaryl, the substituents are each independently selected from any one or more of C1-C10 alkyl or cycloalkyl, C2-C10 alkenyl, C1-C6 alkoxyl, C6-C30 monocyclic aryl or condensed-ring aryl, and C3-C30 monocyclic heteroaryl or condensed-ring heteroaryl.

8. The compound according to claim 1, wherein the compound has a structure as shown in a formula (I-1): 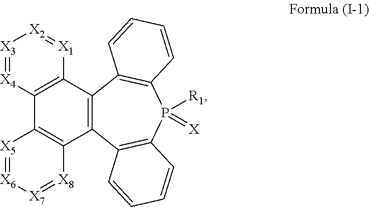
wherein X is selected from O atom or S atom; X₁ to X₈ are each independently selected from C atoms or N atoms, and R₁ is selected from one or more of 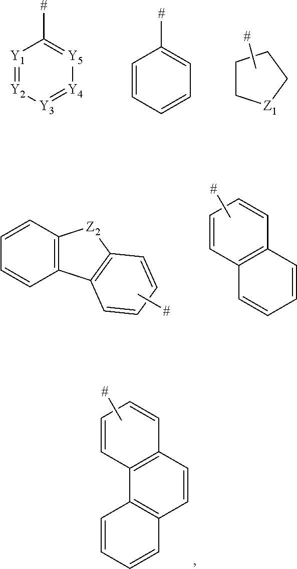
wherein Y₁-Y₅ are each independently selected from C atoms or N atoms, and Z₁ and Z₂ are each independently selected from O atoms, S atoms or N atoms; and # indicates a connection position.

9. The compound according to claim 1, wherein the compound has a structure as shown in a formula (I-2): 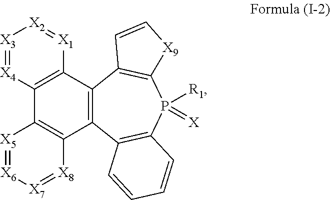
wherein X is selected from O atom or S atom; X₁-X₈ are each independently selected from C atoms or N atoms, X₉ is selected from O atom, S atom or N atom, and
R₁ is selected from one or more of 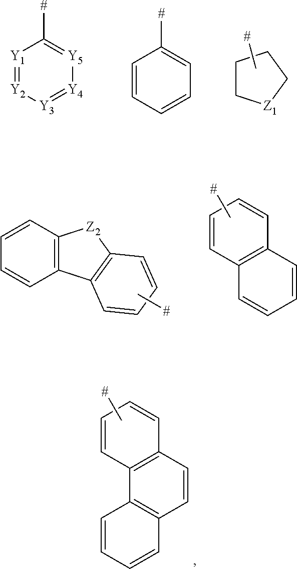
wherein Y₁-Y₅ are each independently selected from C atoms or N atoms, and Z₁ and Z₂ are each independently selected from O atoms, S atoms or N atoms; and # indicates a connection position.

10. The compound according to claim 1, wherein the compound has a structure as shown in a formula (I-3): 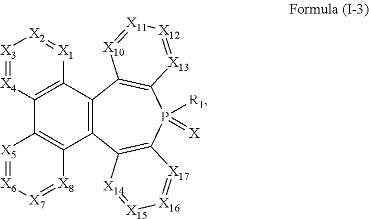
wherein X is selected from O atom or S atom; X₁-X₈ are each independently selected from C atoms or N atoms, and at least one of X₁₀-X₁₇ is N atoms, and
R₁ is selected from one or more of 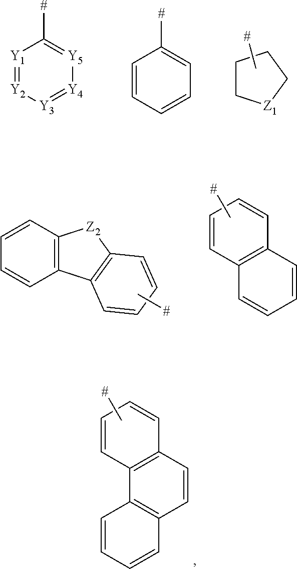
wherein Y₁-Y₅ are each independently selected from C atoms or N atoms, and Z₁ and Z₂ are each independently selected from O atoms, S atoms or N atoms; and # indicates a connection position.

11. The compound according to claim 10, wherein at least one of X₁₀-X₁₃ is N atoms.

12. The compound according to claim 10, wherein at least one of X₁₄-X₁₇ is N atoms.

13. The compound according to claim 1, wherein the compound has a structure as shown in a formula (I-4): 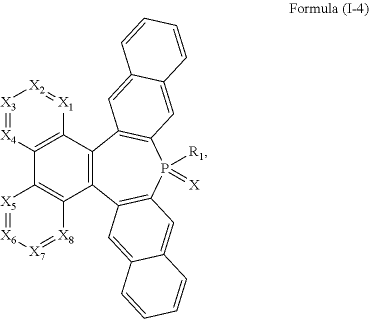
wherein X is selected from O atom or S atom; X₁-X₈ are each independently selected from C atoms or N atoms, and
R₁ is selected from one or more of 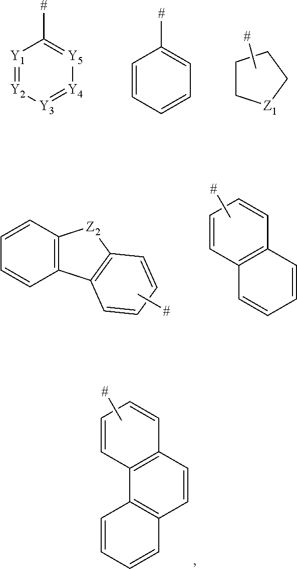
wherein Y₁-Y₅ are each independently selected from C atoms or N atoms, and Z₁ and Z₂ are each independently selected from O atoms, S atoms or N atoms; and # indicates a connection position.

14. The compound according to claim 1, wherein the compound has a structure as shown in a formula (I-5): 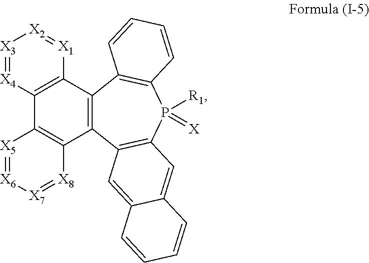
wherein X is selected from O atom or S atom; X₁-X₈ are each independently selected from C atoms or N atoms, and
R₁ is selected from one or more of 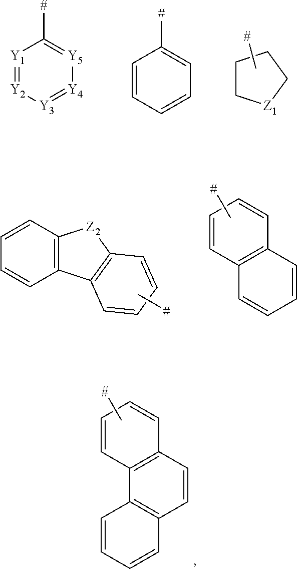
wherein Y₁-Y₅ are each independently selected from C atoms or N atoms, and Z₁ and Z₂ are each independently selected from O atoms, S atoms or N atoms; and # indicates a connection position.

15. The compound according to claim 1, wherein the compound is selected from any one of the following compounds:

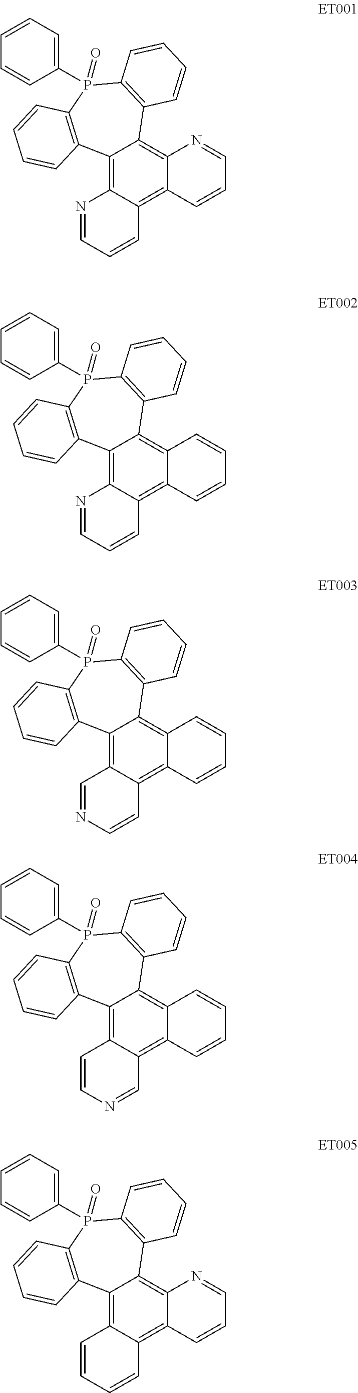 [SMILES: O=P1(c2ccccc2)c2ccccc2-c2c(c3ncccc3c3cccnc23)-c2ccccc21 ; O=P1(c2ccccc2)c2ccccc2-c2c(c3ncccc3c3ccccc23)-c2ccccc21 ; O=P1(c2ccccc2)c2ccccc2-c2c(c3cnccc3c3ccccc23)-c2ccccc21 ; O=P1(c2ccccc2)c2ccccc2-c2c(c3ccncc3c3ccccc23)-c2ccccc21 ; O=P1(c2ccccc2)c2ccccc2-c2c(c3ncccc3c3ccccc23)-c2ccccc21]

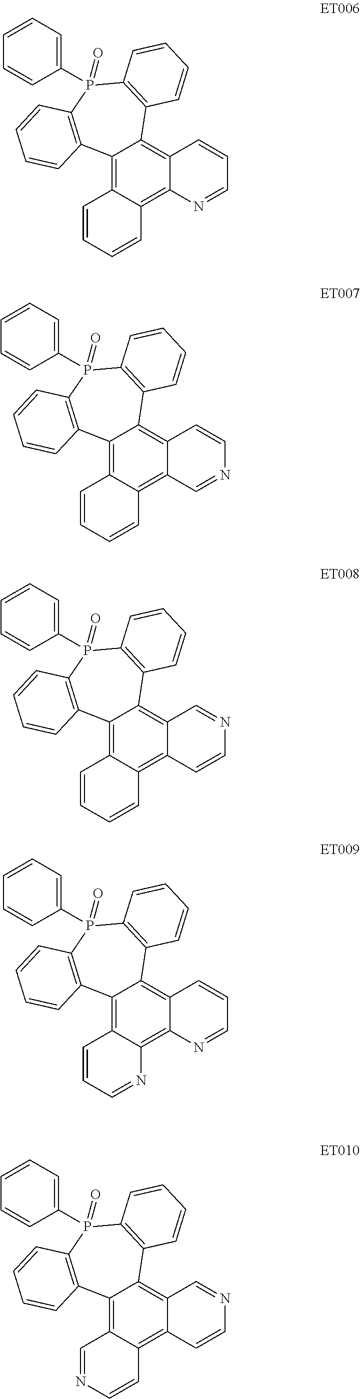 [SMILES: O=P1(c2ccccc2)c2ccccc2-c2c(c3cccnc3c3ccccc23)-c2ccccc21 ; O=P1(c2ccccc2)c2ccccc2-c2c(c3ccncc3c3ccccc23)-c2ccccc21 ; O=P1(c2ccccc2)c2ccccc2-c2c(c3cnccc3c3ccccc23)-c2ccccc21 ; O=P1(c2ccccc2)c2ccccc2-c2c(c3cccnc3c3ncccc23)-c2ccccc21 ; O=P1(c2ccccc2)c2ccccc2-c2c(c3cnccc3c3ccncc23)-c2ccccc21]

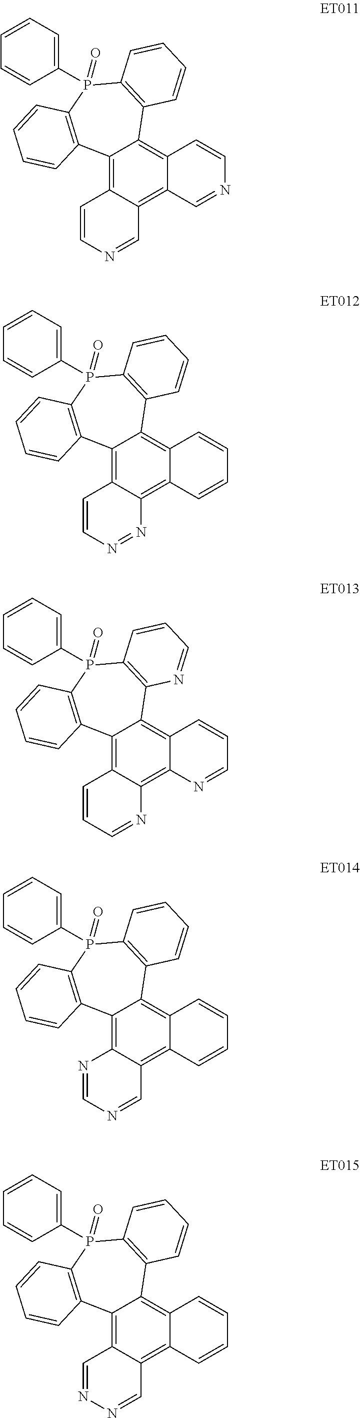 [SMILES: O=P1(c2ccccc2)c2ccccc2-c2c(c3ccncc3c3cnccc23)-c2ccccc21 ; O=P1(c2ccccc2)c2ccccc2-c2c(c3ccnnc3c3ccccc23)-c2ccccc21 ; O=P1(c2ccccc2)c2ccccc2-c2c(c3cccnc3c3ncccc23)-c2ncccc21 ; O=P1(c2ccccc2)c2ccccc2-c2c(c3ncncc3c3ccccc23)-c2ccccc21 ; O=P1(c2ccccc2)c2ccccc2-c2c(c3cnncc3c3ccccc23)-c2ccccc21]

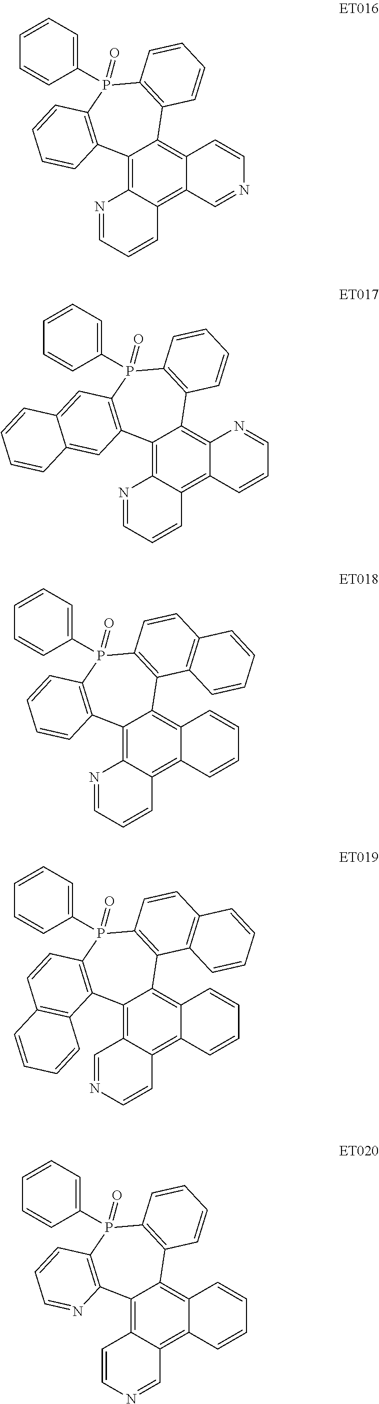 [SMILES: O=P1(c2ccccc2)c2ccccc2-c2c(c3ncccc3c3cnccc23)-c2ccccc21 ; O=P1(c2ccccc2)c2ccccc2-c2c(c3ncccc3c3cccnc23)-c2cc3ccccc3cc21 ; O=P1(c2ccccc2)c2ccccc2-c2c(c3ccccc3c3cccnc23)-c2c1ccc1ccccc21 ; O=P1(c2ccccc2)c2ccc3ccccc3c2-c2c(c3cnccc3c3ccccc23)-c2c1ccc1ccccc21 ; O=P1(c2ccccc2)c2ccccc2-c2c(c3ccncc3c3ccccc23)-c2ncccc21]

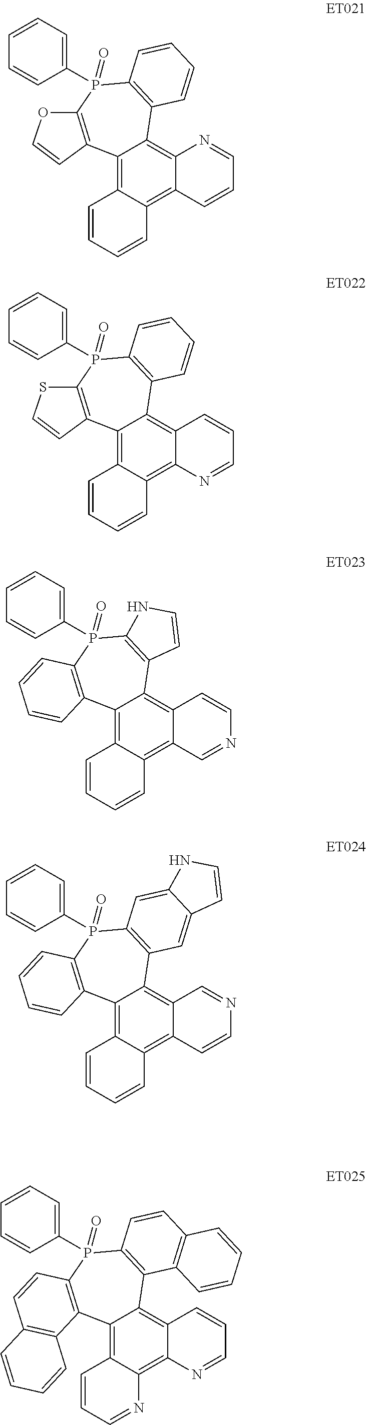 [SMILES: O=P1(c2ccccc2)c2ccccc2-c2c(c3ccccc3c3cccnc23)-c2ccoc21 ; O=P1(c2ccccc2)c2ccccc2-c2c(c3ccccc3c3ncccc23)-c2ccsc21 ; O=P1(c2ccccc2)c2ccccc2-c2c(c3ccncc3c3ccccc23)-c2cc[nH]c21 ; O=P1(c2ccccc2)c2ccccc2-c2c(c3cnccc3c3ccccc23)-c2cc3cc[nH]c3cc21 ; O=P1(c2ccccc2)c2ccc3ccccc3c2-c2c(c3cccnc3c3ncccc23)-c2c1ccc1ccccc21]

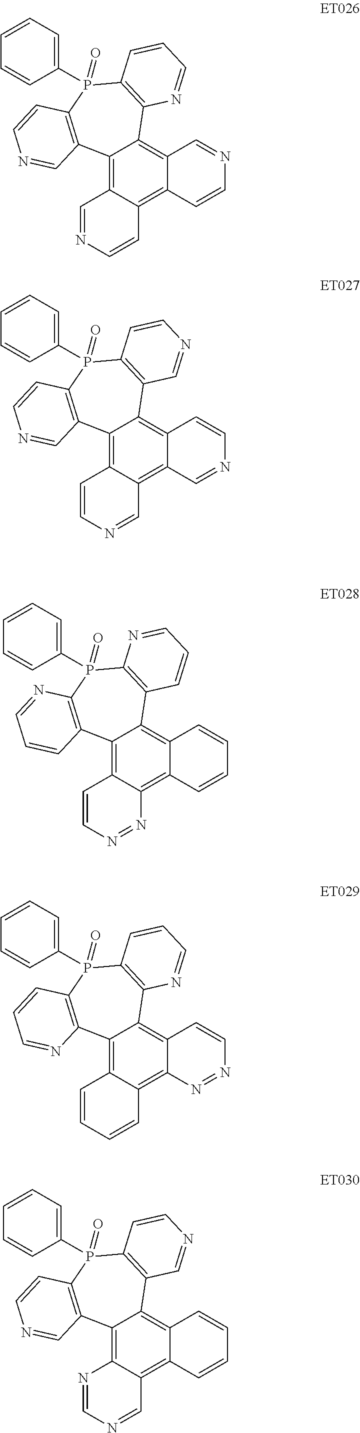 [SMILES: O=P1(c2ccccc2)c2ccncc2-c2c(c3cnccc3c3ccncc23)-c2ncccc21 ; O=P1(c2ccccc2)c2ccncc2-c2c(c3ccncc3c3cnccc23)-c2cnccc21 ; O=P1(c2ccccc2)c2ncccc2-c2c(c3ccnnc3c3ccccc23)-c2cccnc21 ; O=P1(c2ccccc2)c2cccnc2-c2c(c3ccnnc3c3ccccc23)-c2ncccc21 ; O=P1(c2ccccc2)c2ccncc2-c2c(c3ncncc3c3ccccc23)-c2cnccc21]

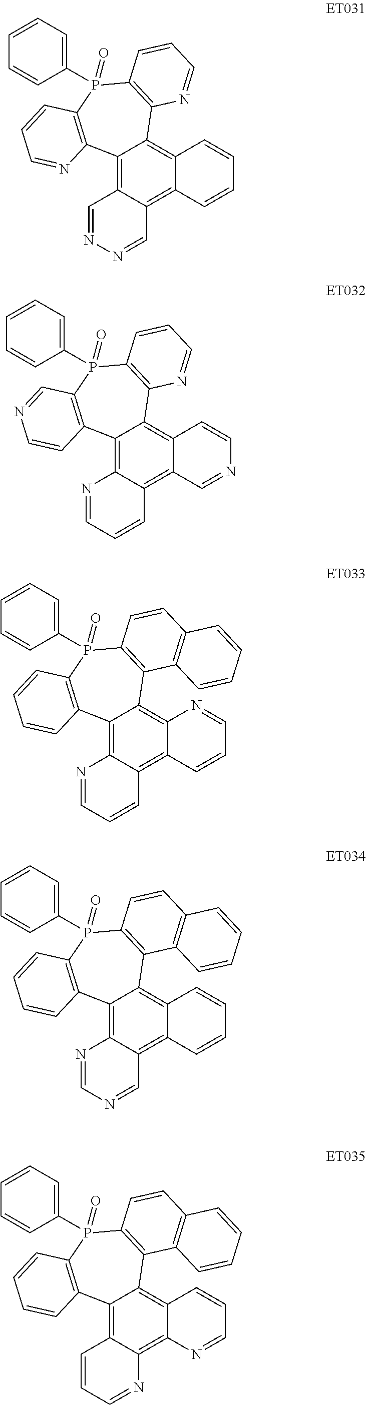 [SMILES: O=P1(c2ccccc2)c2cccnc2-c2c(c3cnncc3c3ccccc23)-c2ncccc21 ; O=P1(c2ccccc2)c2cnccc2-c2c(c3ccncc3c3cccnc23)-c2ncccc21 ; O=P1(c2ccccc2)c2ccccc2-c2c(c3ncccc3c3cccnc23)-c2c1ccc1ccccc21 ; O=P1(c2ccccc2)c2ccccc2-c2c(c3ccccc3c3cncnc23)-c2c1ccc1ccccc21 ; O=P1(c2ccccc2)c2ccccc2-c2c(c3cccnc3c3ncccc23)-c2c1ccc1ccccc21]

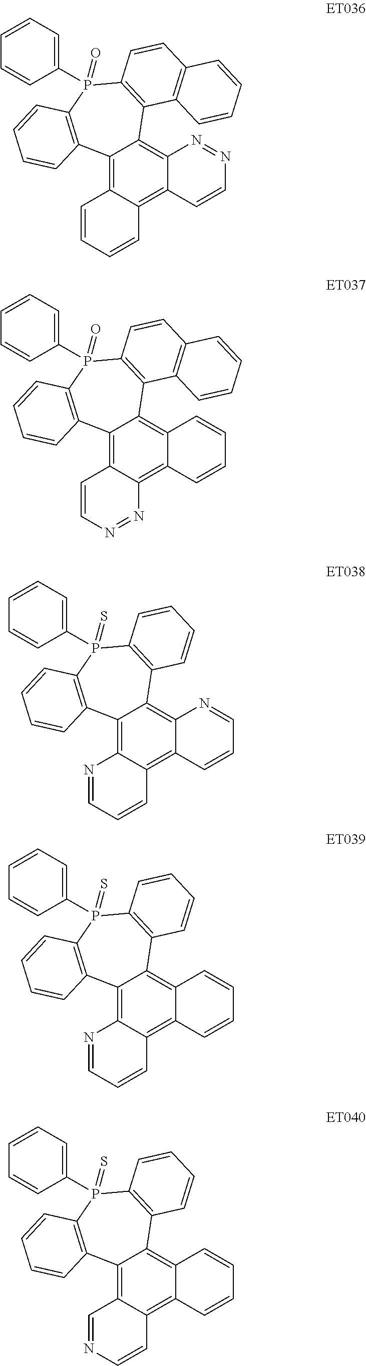 [SMILES: O=P1(c2ccccc2)c2ccccc2-c2c(c3nnccc3c3ccccc23)-c2c1ccc1ccccc21 ; O=P1(c2ccccc2)c2ccccc2-c2c(c3ccccc3c3nnccc23)-c2c1ccc1ccccc21 ; S=P1(c2ccccc2)c2ccccc2-c2c(c3ncccc3c3cccnc23)-c2ccccc21 ; S=P1(c2ccccc2)c2ccccc2-c2c(c3ncccc3c3ccccc23)-c2ccccc21 ; S=P1(c2ccccc2)c2ccccc2-c2c(c3cnccc3c3ccccc23)-c2ccccc21]

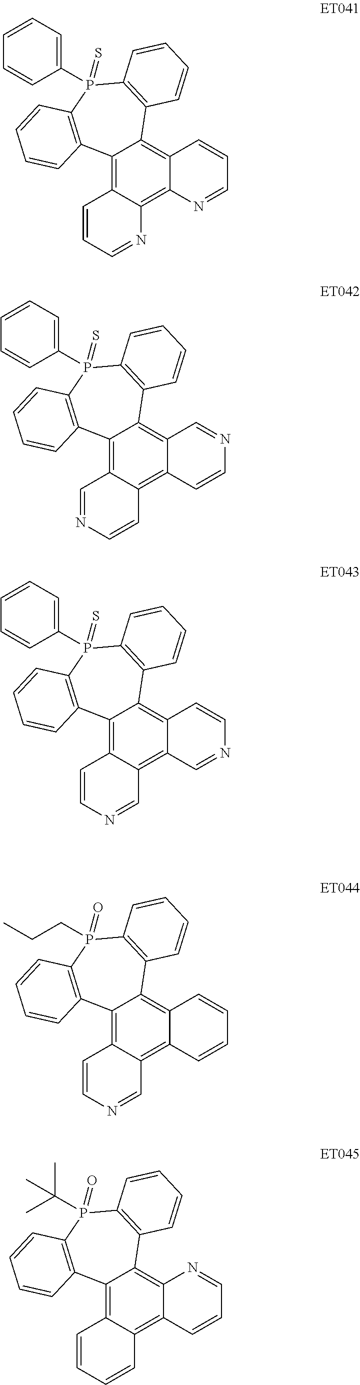 [SMILES: S=P1(c2ccccc2)c2ccccc2-c2c(c3cccnc3c3ncccc23)-c2ccccc21 ; S=P1(c2ccccc2)c2ccccc2-c2c(c3cnccc3c3ccncc23)-c2ccccc21 ; S=P1(c2ccccc2)c2ccccc2-c2c(c3ccncc3c3cnccc23)-c2ccccc21 ; CCCP1(=O)c2ccccc2-c2c(c3ccncc3c3ccccc23)-c2ccccc21 ; CC(C)(C)P1(=O)c2ccccc2-c2c(c3ncccc3c3ccccc23)-c2ccccc21]

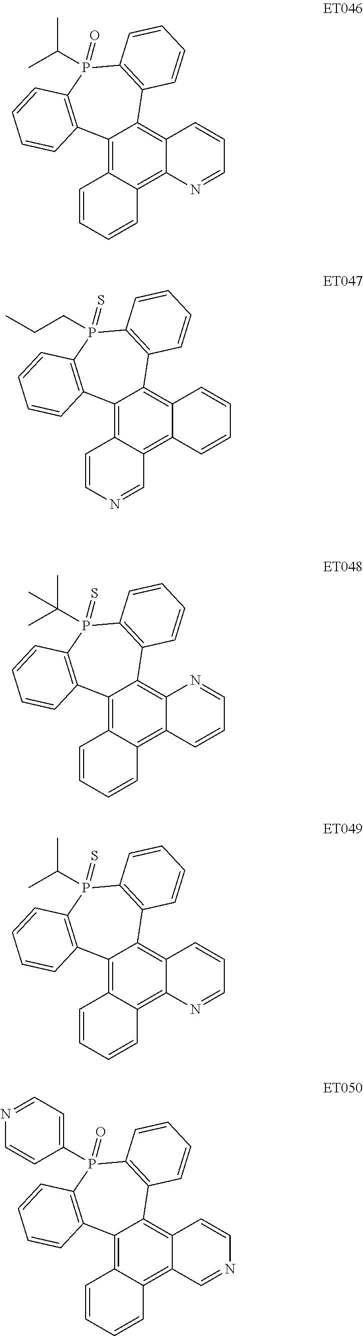 [SMILES: CC(C)P1(=O)c2ccccc2-c2c(c3cccnc3c3ccccc23)-c2ccccc21 ; CCCP1(=S)c2ccccc2-c2c(c3ccncc3c3ccccc23)-c2ccccc21 ; CC(C)(C)P1(=S)c2ccccc2-c2c(c3ncccc3c3ccccc23)-c2ccccc21 ; CC(C)P1(=S)c2ccccc2-c2c(c3cccnc3c3ccccc23)-c2ccccc21 ; O=P1(c2ccncc2)c2ccccc2-c2c(c3ccncc3c3ccccc23)-c2ccccc21]

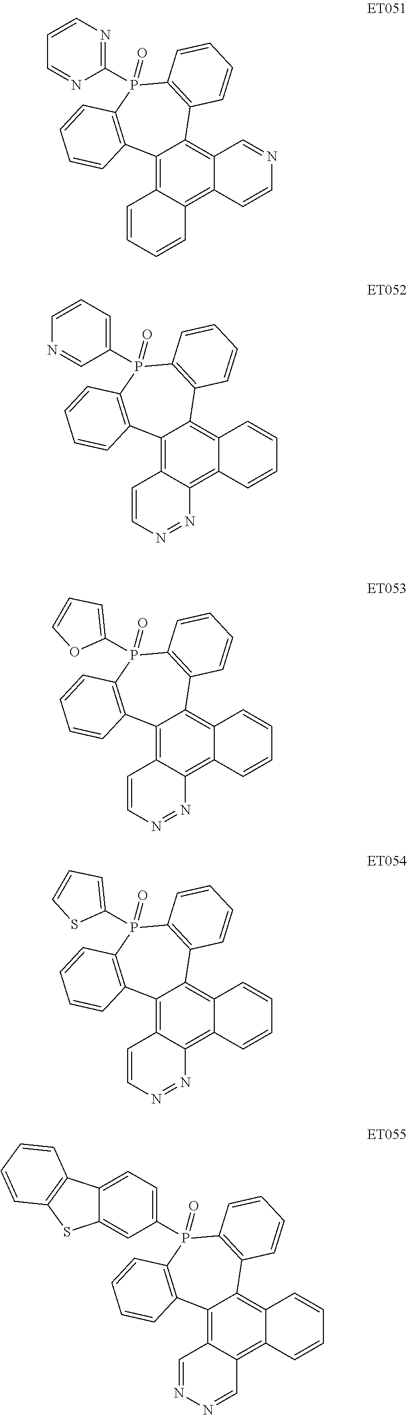 [SMILES: O=P1(c2ncccn2)c2ccccc2-c2c(c3cnccc3c3ccccc23)-c2ccccc21 ; O=P1(c2cccnc2)c2ccccc2-c2c(c3ccnnc3c3ccccc23)-c2ccccc21 ; O=P1(c2ccco2)c2ccccc2-c2c(c3ccnnc3c3ccccc23)-c2ccccc21 ; O=P1(c2cccs2)c2ccccc2-c2c(c3ccnnc3c3ccccc23)-c2ccccc21 ; O=P1(c2ccc3c(c2)sc2ccccc23)c2ccccc2-c2c(c3cnncc3c3ccccc23)-c2ccccc21]

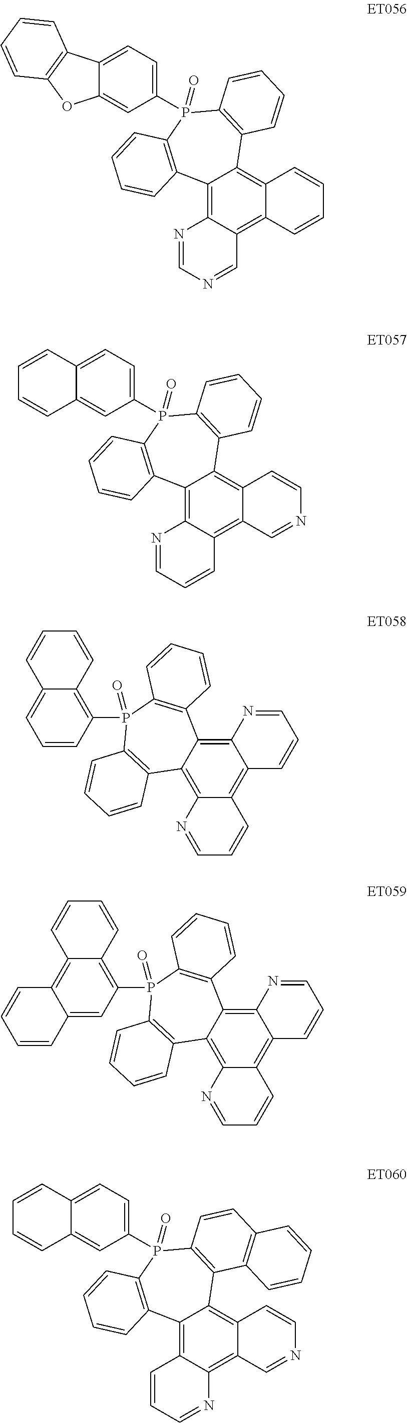 [SMILES: O=P1(c2ccc3c(c2)oc2ccccc23)c2ccccc2-c2c(c3ncncc3c3ccccc23)-c2ccccc21 ; O=P1(c2ccc3ccccc3c2)c2ccccc2-c2c(c3ncccc3c3cnccc23)-c2ccccc21 ; O=P1(c2cccc3ccccc23)c2ccccc2-c2c(c3ncccc3c3cccnc23)-c2ccccc21 ; O=P1(c2cc3ccccc3c3ccccc23)c2ccccc2-c2c(c3ncccc3c3cccnc23)-c2ccccc21 ; O=P1(c2ccc3ccccc3c2)c2ccccc2-c2c(c3ccncc3c3ncccc23)-c2c1ccc1ccccc21]

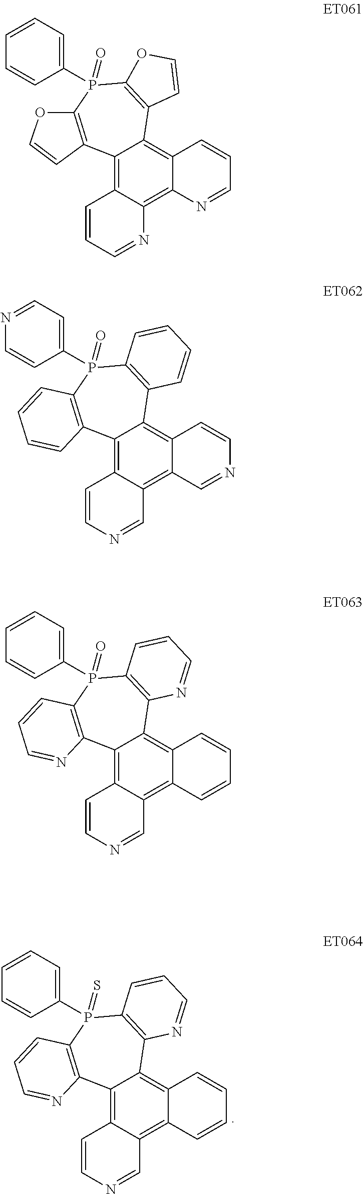 [SMILES: O=P1(c2ccccc2)c2occc2-c2c(c3cccnc3c3ncccc23)-c2ccoc21 ; O=P1(c2ccncc2)c2ccccc2-c2c(c3ccncc3c3cnccc23)-c2ccccc21 ; O=P1(c2ccccc2)c2cccnc2-c2c(c3ccncc3c3ccccc23)-c2ncccc21 ; S=P1(c2ccccc2)c2cccnc2-c2c(c3ccncc3c3ccccc23)-c2ncccc21]

16. The compound according to claim 1, wherein the compound is selected from any one of the following compounds:

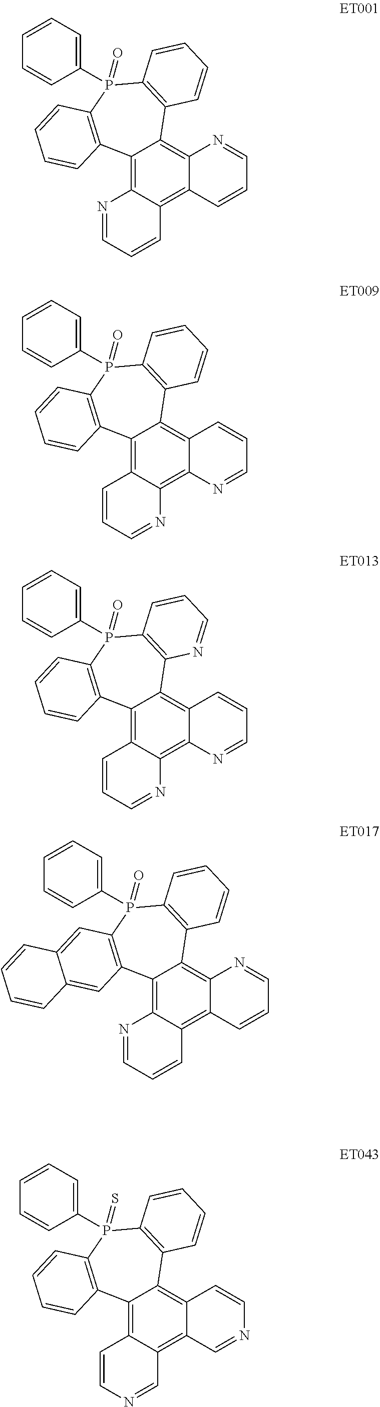 [SMILES: O=P1(c2ccccc2)c2ccccc2-c2c(c3ncccc3c3cccnc23)-c2ccccc21 ; O=P1(c2ccccc2)c2ccccc2-c2c(c3cccnc3c3ncccc23)-c2ccccc21 ; O=P1(c2ccccc2)c2ccccc2-c2c(c3cccnc3c3ncccc23)-c2ncccc21 ; O=P1(c2ccccc2)c2ccccc2-c2c(c3ncccc3c3cccnc23)-c2cc3ccccc3cc21 ; S=P1(c2ccccc2)c2ccccc2-c2c(c3ccncc3c3cnccc23)-c2ccccc21]

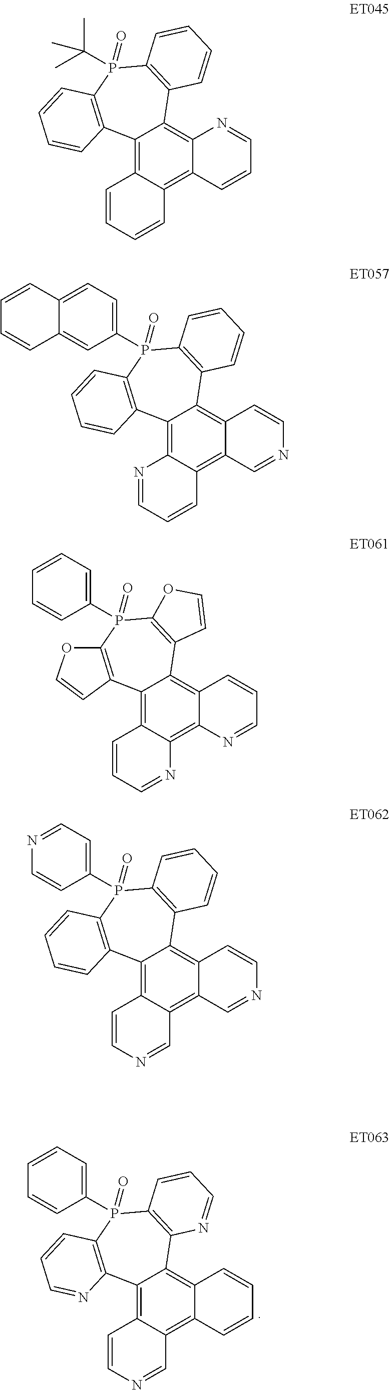 [SMILES: CC(C)(C)P1(=O)c2ccccc2-c2c(c3ncccc3c3ccccc23)-c2ccccc21 ; O=P1(c2ccc3ccccc3c2)c2ccccc2-c2c(c3ncccc3c3cnccc23)-c2ccccc21 ; O=P1(c2ccccc2)c2occc2-c2c(c3cccnc3c3ncccc23)-c2ccoc21 ; O=P1(c2ccncc2)c2ccccc2-c2c(c3ccncc3c3cnccc23)-c2ccccc21 ; O=P1(c2ccccc2)c2cccnc2-c2c(c3ccncc3c3ccccc23)-c2ncccc21]

17. An organic electroluminescence device, comprising a first electrode and a second electrode, and an organic function layer between the first electrode and the second electrode, the organic function layer comprising an electron transport layer, wherein an electron transport material of the electron transport layer includes the compound according to claim 1.

18. The organic electroluminescence device according to claim 17, wherein the organic function layer also includes a hole barrier layer, and an electron transport material of the hole barrier layer includes the compound according to claim 1.

19. A display device, wherein the display device includes the organic electroluminescence device according to claim 17.
